(19) United States
(12) Patent Application Publication
(10) Pub. No.: US 2011/0175535 A1
(43) Pub. Date: Jul. 21, 2011

(54) SEMICONDUCTOR DEVICE, METHOD FOR MANUFACTURING SAME AND DISPLAY DEVICE

(75) Inventor: Naoki Makita, Osaka-shi (JP)

(73) Assignee: SHARP KABUSHIKI KAISHA, Osaka-shi, Osaka (JP)

(21) Appl. No.: 13/121,441

(22) PCT Filed: Sep. 29, 2009
(86) PCT No.: PCT/JP2009/004971

§ 371 Date: Mar. 29, 2011

(30) Foreign Application Priority Data
Sep. 30, 2008 (JP) 2008-253233

(51) Int. Cl. H05B 37/02; H01L 29/04; H01L 21/336; G06F 3/042

(52) U.S. Cl. 315/158; 257/59; 438/164; 345/175; 257/E21.412; 257/E29.003

(57) ABSTRACT

A semiconductor device 100 includes a thin-film transistor, which is supported by a substrate 101 and which includes a crystalline semiconductor layer 107 with a channel region 115 and source and drain regions 113, a gate insulating film 108 that is arranged to cover the crystalline semiconductor layer 107, and a gate electrode 109 that is arranged on the gate insulating film 108 to control the conductivity of the channel region; and a thin-film diode, which is also supported by the substrate 101 and which includes an amorphous semiconductor layer 110 that has at least an n-type region 114 and a p-type region 118. The amorphous semiconductor layer 110 has been deposited on the gate insulating film 108 in contact with the surface of the gate insulating film 108. The n-type or p-type region 114 or 118 and the source and drain regions 113 have the same dopant element.

### TECHNICAL FIELD

The present invention relates to a semiconductor device including a thin-film transistor (TFT) and a thin-film diode (TFD) and a method for fabricating such a device, and also relates to a display device.

### BACKGROUND ART

Recently, a semiconductor device including a thin-film transistor (TFT) and a thin-film diode (TFD) on the same substrate and electronic devices with such a semiconductor device have been developed. Such a semiconductor device can be fabricated by making the respective semiconductor layers of the TFT and TFD of the same crystalline semiconductor film on the substrate.

The device characteristics of the TFT and TFD on the same substrate are affected most significantly by the degree of crystallinity of the semiconductor layer to be their active regions. To make a crystalline semiconductor layer of quality on a glass substrate, it is most common to crystalline an amorphous semiconductor film by irradiating it with a laser beam. According to another method, the amorphous semiconductor film may be heated and crystallized after a catalyst element that promotes its crystallization has been added thereto. A third method is to crystallize the amorphous semiconductor film by the latter method and then irradiate the resultant crystalline semiconductor film with a laser beam to further increase its degree of crystallinity. As a result, compared to a normal crystalline semiconductor film that has been crystallized just by being irradiated with a laser beam after having gone through a low-temperature heat treatment process for only a short time, a semiconductor film of better quality, of which the crystallographic plane orientations are aligned to a higher degree, can be obtained.

Patent Document No. 1 discloses an image sensor including, on the same substrate, a photosensor unit that uses a TFD and a driver that uses a TFT. According to Patent Document No. 1, the respective semiconductor layers of the TFT and TFD are obtained by crystallizing an amorphous semiconductor film that has been deposited on a substrate.

If the TFT and TFD form integral parts of a single semiconductor device on the same substrate in this manner, not just the overall size of the semiconductor device but also the number of required parts can be reduced, thus cutting down the cost significantly. On top of that, products with new functions, which could not be achieved by conventional combinations of parts, can also be provided.

On the other hand, Patent Document No. 2 discloses a technique for using the same semiconductor film of amorphous silicon to form a TFT of crystalline silicon (which will be referred to herein as a “crystalline silicon TFT”) and a TFD of amorphous silicon (which will be referred to herein as an “amorphous silicon TFD”) on the same substrate. Specifically, a catalyst element that promotes the crystallization of amorphous silicon is added to only a portion of the amorphous silicon film on the substrate to be the active region of the TFT. After that, a heat treatment process is carried out, thereby obtaining a silicon film, of which only the portion to be the active region of the TFT has been crystallized but a portion to be the TFD remains amorphous. By using such a silicon film, the crystalline silicon TFT and the amorphous silicon TFD can be fabricated on the same substrate more easily.

Furthermore, according to Patent Document No. 3, the same semiconductor film (of amorphous silicon) is used to make a photosensor TFT functioning as a photosensor and a switching TFT functioning as a switching element. By making the silicon film that defines the channel region of the photosensor TFT thicker than the silicon film that defines the source and drain regions thereof or the active region of the switching TFT, the sensitivity of the photosensor is increased. According to that patent document, to make the thicknesses of the respective silicon films of those TFTs different from each other, when a photolithographic process is carried out to divide the amorphous silicon film into a number of islands, the amorphous silicon film has its thickness partially reduced by half exposure process that uses a gray tone mask. Patent Document No. 3 also discloses that by irradiating the amorphous silicon film with a laser beam, those thinned portions of the amorphous silicon film (i.e., portions to be the source and drain regions of each photosensor TFT and the portion to be the active region of each switching TFT) are crystallized but the other non-thinned portion (i.e., the portion to be the channel region of the photosensor TFT) is left amorphous.

### CITATION LIST

### Patent Literature

Patent Document No. 1: Japanese Patent Application Laid-Open Publication No. 6-275808
Patent Document No. 2: Japanese Patent Application Laid-Open Publication No. 6-275807
Patent Document No. 3: Japanese Patent Application Laid-Open Publication No. 2005-72126

### SUMMARY OF INVENTION

### Technical Problem

According to Patent Document No. 1, the respective semiconductor layers of the TFT and the TFD are formed at the same time by crystallizing the same crystalline semiconductor film. The TFT and TFD are required to have different device characteristics according to their applications. According to such a method, however, it is difficult for both of the TFT and the TFD to meet their required device characteristics at the same time.

On the other hand, if only a portion of the same amorphous semiconductor film is selectively crystallized as in Patent Documents Nos. 2 and 3 to form a crystalline silicon TFT of the crystallized portion and an amorphous silicon TFD of the remaining amorphous portion of the film, it is certainly possible to improve the characteristics of the crystalline silicon TFT by controlling the crystal growing conditions. In that case, however, some of the hydrogen atoms originally included in the amorphous silicon film will be lost during the heat treatment process of crystallizing the portion of the amorphous silicon film into crystalline silicon. As a result, an amorphous silicon TFD with good electrical characteristics cannot be formed of such a portion that is left amorphous after the heat treatment process. Specifically, in an amorphous silicon film as deposited, silicon atoms are tightly bonded with hydrogen atoms, thus leaving no dangling bonds at all (i.e., terminating). However, during the annealing process to crystallize the amorphous silicon film, the bonds between the silicon and hydrogen atoms are broken, and some hydrogen atoms are lost, thus turning the amorphous silicon film into an amorphous silicon of poor quality with a lot of dangling bonds of silicon.

On top of that, there is another problem with the method of Patent Document No. 3. Specifically, according to Patent Document No. 3, the silicon film that defines the photosensor TFT can be thicker than the one that defines the switching TFT. That is why this method does contribute to increasing the sensitivity of the photosensor effectively. Nevertheless, since a half exposure process and a half etching process should be done to make the silicon film have varying thicknesses, the manufacturing process gets complicated. In addition, according to these techniques, the thickness of a particular region is selectively reduced by etching away only a portion of the silicon film in that particular region. In that case, however, it is very difficult to precisely control the thickness of that region to have a reduced thickness. As a result, the silicon film of the switching TFTs could have significantly varying thicknesses and the intended good performance could not be achieved.

As can be seen, if a semiconductor device is fabricated by forming TFTs and TFDs on the same substrate by any of those conventional techniques, it is difficult for the TFTs and TFDs to achieve their required performances at the same time. As a result, a high-performance semiconductor device could not be obtained.

It is therefore an object of the present invention to provide a semiconductor device that includes a thin-film transistor and a thin-film diode on the same substrate and that can have the thin-film transistor and thin-film diode achieve their expected performances.

### Solution to Problem

A semiconductor device according to the present invention includes: a substrate; a thin-film transistor, which is supported by the substrate and which includes a crystalline semiconductor layer with a channel region and source and drain regions, a gate insulating film that is arranged to cover the crystalline semiconductor layer, and a gate electrode that is arranged on the gate insulating film to control the conductivity of the channel region; and a thin-film diode, which is also supported by the substrate and which includes an amorphous semiconductor layer that has at least an n-type region and a p-type region. The amorphous semiconductor layer has been deposited on the gate insulating film in contact with the surface of the gate insulating film. The n-type or p-type region and the source and drain regions have the same dopant element.

In one preferred embodiment, the thickness d2 of the amorphous semiconductor layer is greater than the thickness d1 of the crystalline semiconductor layer.

The thin-film transistor may further include an interlevel dielectric layer that contacts with the upper surface of the gate electrode. The thin-film diode may further include an interlevel dielectric layer that contacts with the upper surface of the amorphous semiconductor layer. And the respective interlevel dielectric layers of the thin-film transistor and the thin-film diode may be made of the same insulating film.

In another preferred embodiment, the depth Dd of a peak of the concentration profile of the same dopant element as measured in the thickness direction, and from the upper surface, of the n-type or p-type region is substantially equal to the depth Dt of another peak of the concentration profile of the same dopant element as measured in the thickness direction of the source and drain regions from the upper surface of the gate insulating film.

It is preferred that the thickness d2 of the amorphous semiconductor layer be greater than the sum (d1+d3) of the thickness d1 of the crystalline semiconductor layer and the thickness d3 of the gate insulating film.

In this particular preferred embodiment, the thickness d3 of the gate insulating film may be measured on the source and drain regions of the crystalline semiconductor layer.

The amorphous semiconductor layer preferably includes an intrinsic region between the n-type and p-type regions.

The amorphous semiconductor layer is preferably a hydrogenated amorphous semiconductor layer in which dangling bonds of semiconductor atoms have been inactivated with hydrogen atoms.

The substrate may be light-transmissive, and the device may further include an opaque layer between the amorphous semiconductor layer and the substrate.

It is preferred that the opaque layer and the crystalline semiconductor layer be made of the same semiconductor film.

A method for fabricating a semiconductor device according to the present invention includes the steps of: (a) providing a substrate, of which the surface is already covered with a crystalline semiconductor film; (b) patterning a portion of the crystalline semiconductor film into a first semiconductor island that will define the active region of a thin-film transistor; (c) depositing a gate insulating film over the first semiconductor island; (d) stacking an amorphous semiconductor film on the gate insulating film; and (e) patterning a portion of the amorphous semiconductor film into a second semiconductor land that will define the active region of a thin-film diode.

In one preferred embodiment, the amorphous semiconductor film is thicker than the crystalline semiconductor film. More preferably, the thickness of the amorphous semiconductor film is greater than the combined thickness of the crystalline semiconductor film and the gate insulating film.

The method may further include the step of forming a gate electrode for the thin-film transistor on the gate insulating film after the step (c) has been performed. And the thickness of the amorphous semiconductor film may be greater than the combined thickness of exposed portions of the crystalline semiconductor film and the gate insulating film that are not masked with the gate electrode.

In another preferred embodiment, the method further includes the step of doping portions of the first semiconductor island to be source and drain regions and a portion of the second semiconductor island to be an n-type or p-type region with the same dopant element simultaneously after the step (e) has been performed.

The method may further include, after the step (e), the steps of: (f) doping portions of the first semiconductor island to be source and drain regions with a first dopant element through the gate insulating film; (g) doping a portion of the second semiconductor island to be an n-type region with an n-type dopant element; and (h) doping another portion of the second semiconductor island to be a p-type region with a p-type dopant element.

In this particular preferred embodiment, the first dopant element includes an n-type dopant element, and the steps (f) and (g) are performed simultaneously.

In an alternative preferred embodiment, the first dopant element includes a p-type dopant element, and the steps (f) and (h) are performed simultaneously.

In still another preferred embodiment, the first semiconductor island is comprised of islands of semiconductor regions including islands to be the respective active regions of n-channel and p-channel thin-film transistors. The step (f) includes the steps of (f1) doping one of the islands of semiconductor regions of the first semiconductor island, which will form part of the n-channel thin-film transistor, with the n-type dopant element through the gate insulating film, and (f2) doping another one of the islands of semiconductor regions of the first semiconductor island, which will form part of the p-channel thin-film transistor, with the p-type dopant element through the gate insulating film. The steps (f1) and (g) are performed simultaneously. And the steps (f2) and (h) are also performed simultaneously.

In yet another preferred embodiment, the method further includes the step of forming a gate electrode for the thin-film transistor on the gate insulating film after the step (c) has been performed. The step (f) includes introducing the first dopant element using the gate electrode as a mask. The method further includes the step of irradiating that portion of the first semiconductor island, which has been doped with the first dopant element, with a laser beam through the gate insulating film, thereby activating the first dopant element in the first semiconductor island after the steps (f), (g) and (h) have been performed. The thickness d3 (nm) of an exposed portion of the gate insulating film that is not masked with the gate electrode, the wavelength λ (nm) of the laser beam, and the refractive index n of the gate insulating film satisfy the inequality: m×λ/(4×n)−15≦d3≦m×λ/(4×n)+15, where m is an integer that is equal to or greater than one.

The substrate may be light-transmissive. And the method may further include the step of forming an opaque layer for cutting light that has come from under the opposite surface of the substrate on a region of the substrate, which will be located under the second semiconductor island to be the active region of a thin-film diode, before the step (c) is performed.

The step (b) may include patterning the crystalline semiconductor film into the first semiconductor island to be the active region of a thin-film transistor and at least a part of the opaque layer simultaneously.

The step (a) may include the steps of: (a1) providing a substrate, of which the surface is already covered with another amorphous semiconductor film; and (a2) irradiating and crystallizing that another amorphous semiconductor film with a laser beam, thereby forming a crystalline semiconductor film.

Alternatively, the step (a) may include the steps of: (a1) providing a substrate, of which the surface is already covered with another amorphous semiconductor film; (a2) adding a catalyst element, which promotes crystallization, to that another amorphous semiconductor film; and (a3) heating and crystallizing that another amorphous semiconductor film to which the catalyst element has been added, thereby forming a crystalline semiconductor film.

Another semiconductor device according to the present invention is fabricated by a method according to any of the preferred embodiments of the present invention described above.

A display device according to the present invention includes: a display area including a plurality of display units; and a frame area, which surrounds the display area. The device further includes a photosensor unit with a thin-film diode. Each display unit includes an electrode and a thin-film transistor that is connected to the electrode. The thin-film transistor and the thin-film diode have been formed on the same light-transmissive substrate. The thin-film transistor includes a crystalline semiconductor layer with a channel region and source and drain regions, a gate insulating film that is arranged to cover the crystalline semiconductor layer, and a gate electrode that is arranged on the gate insulating film to control the conductivity of the channel region. The thin-film diode includes an amorphous semiconductor layer that has at least an n-type region and a p-type region. The amorphous semiconductor layer has been deposited on the gate insulating film in contact with the surface of the gate insulating film. And wherein the n-type or p-type region and the source and drain regions have the same dopant element.

In one preferred embodiment, the display unit further includes a backlight and a backlight controller for controlling the luminance of the light emitted from the backlight, and the photosensor unit generates an illuminance signal representing the illuminance of external light and outputs the illuminance signal to the backlight controller.

In another preferred embodiment, the display device further includes multiple optical touchscreen sensors, each of which includes the photosensor unit and is arranged in the display area for associated one, two or more of the display units.

### Advantageous Effects of Invention

According to the present invention, in a semiconductor device including a TFT and a TFD on the same substrate, the semiconductor layers of the TFT and the TFD have been formed of mutually different semiconductor films, and therefore, can be optimized according to the device performances required. Consequently, the respective device performances that the TFT and the TFD should have can be achieved at the same time.

In addition, according to the present invention, a high-performance semiconductor device including a TFT and a TFD can be fabricated easily without increasing the number of manufacturing processing steps or the manufacturing cost. As a result, a product of a smaller size and with improved performance can be provided at a reduced cost.

More particularly, since an amorphous semiconductor layer to be the active region of a TFD can be formed after a crystalline semiconductor layer to be the active region of a TFT has been formed, it is possible to prevent the electric characteristic of the amorphous semiconductor layer from being affected by the crystal-growing process to form the crystalline semiconductor layer. On top of that, if the doping process step is performed on the TFT and on the TFD simultaneously, the number of manufacturing processing steps can be further reduced.

The present invention can be used effectively in a liquid crystal display device with a sensor function. If the present invention is applied to a display device including a TFT for use to make a driver, a TFT to switch a pixel electrode, and a TFD for use as a photosensor, for example, then a TFT with high field effect mobility and a low threshold voltage and a TFD with a low dark current value and a high SNR with respect to light (i.e., the ratio of the amount of current to flow in bright state to that of current to flow in dark state) can be formed on the same substrate, which is beneficial. Particularly if the semiconductor layer is optimized in the channel region that has significant influence on the field effect mobility of the TFT and in the intrinsic region that has great impact on the photosensitivity of the TFD, the best device performances are realized for the respective semiconductor components.

### BRIEF DESCRIPTION OF DRAWINGS

FIG. 1(a) is a cross-sectional view schematically illustrating a preferred embodiment of a semiconductor device according to the present invention, and FIG. 1(b) illustrates the concentration profiles of a dopant element in the respective semiconductor layers of a TFT and a TED.

FIG. 2 is a schematic cross-sectional view illustrating a semiconductor device as a first preferred embodiment of the present invention.

FIGS. 3(A) through 3(H) are schematic cross-sectional views illustrating respective manufacturing process steps to make the semiconductor device of the first preferred embodiment of the present invention.

FIGS. 4(A) through 4(H) are schematic cross-sectional views illustrating respective manufacturing process steps to make a semiconductor device as a second preferred embodiment of the present invention.

FIGS. 5(A) through 5(E) are schematic cross-sectional views illustrating respective manufacturing process steps to make a semiconductor device as a third preferred embodiment of the present invention.

FIGS. 6(F) through 6(H) are schematic cross-sectional views illustrating respective manufacturing process steps to make a semiconductor device as a third preferred embodiment of the present invention.

FIGS. 7(I) through 7(K) are schematic cross-sectional views illustrating respective manufacturing process steps to make a semiconductor device as a third preferred embodiment of the present invention.

FIG. 8 is a graph showing the dependence of a crystal grain size on the radiation energy of a laser beam.

FIG. 9 is a circuit diagram illustrating a photosensor TFD.

FIG. 10 illustrates a configuration for a photosensing type touchscreen panel.

FIG. 11 is a plan view schematically illustrating the rear substrate of a touchscreen panel LCD as a fourth preferred embodiment of the present invention.

FIG. 12 is a perspective view illustrating a liquid crystal display device with an ambient light sensor according to the fourth preferred embodiment of the present invention.

### DESCRIPTION OF EMBODIMENTS

A semiconductor device according to the present invention is characterized in that a thin-film transistor that has been formed using a crystalline semiconductor layer and a thin-film diode that has been formed using an amorphous semiconductor layer are integrated together on the same substrate, and that the amorphous semiconductor layer is arranged in contact with the surface of a gate insulating film, and that the n-type or p-type region of the thin-film diode and the source/drain regions of the thin-film transistor include the same dopant element.

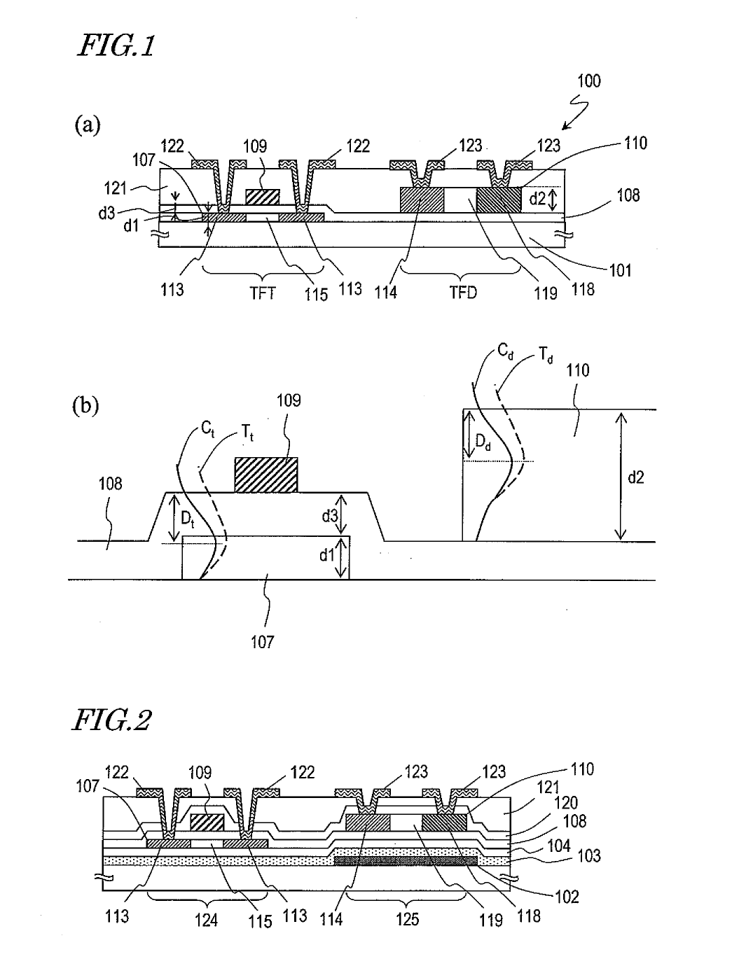

Hereinafter, the configuration of a semiconductor device according to the present invention will be described in further detail with reference to the accompanying drawings. FIG. 1(a) is a cross-sectional view schematically illustrating a preferred embodiment of a semiconductor device according to the present invention. The semiconductor device 100 includes a substrate 101 and a thin-film transistor (TFT) and a thin-film diode (TFD) that are supported by the substrate 101. The TFT of this preferred embodiment includes a semiconductor layer 107 that defines a channel region 115 and source and drain regions 113, a gate insulating film 108 that is arranged to cover the semiconductor layer 107, and a gate electrode 109 that is arranged on the gate insulating film 108 to control the conductivity of the channel region 115. The semiconductor layer 107 is a crystalline semiconductor layer. On the other hand, the TFD of this preferred embodiment includes a semiconductor layer 110 that has an intrinsic region 119b, an n-type region 114 and a p-type region 118. The semiconductor layer 110 is an amorphous semiconductor layer and has been deposited on the gate insulating film 108 in contact with the upper surface of the gate insulating film 108.

The n-type or p-type region 114 or 118 and the source and drain regions 113 have the same dopant element. That is to say, if the TFT is an n-channel TFT, the source/drain regions 113 and the n-type region 114 of the TFD have the same n-type dopant element. On the other hand, if the TFT is a p-channel TFT, then the source/drain regions 113 and the p-type region 118 have the same dopant element. It should be noted that the semiconductor layer 110 needs to have at least the n-type region 114 and the p-type region 118 and could have no intrinsic region 119.

In this preferred embodiment, an interlevel dielectric layer 121 has been deposited on the upper surface of the gate electrode 109 of the TFT and on the upper surface of the semiconductor layer 110 of the TFD. It is preferred that the TFT and TFD share the same insulating film as their interlevel dielectric layer 121 because the manufacturing process can be simplified in that case.

In this semiconductor device 100, the respective semiconductor layers 107 and 110 of the TFT and TFD are two separate layers that have been formed by patterning two different semiconductor films. That is why these two types of components can achieve the best performances expected. Specifically, by optimizing the film qualities, thicknesses and crystal state of these semiconductor layers 107 and 110, their best performances can be accomplished.

Particularly a TFT for use to make a driver often needs to have a field-effect mobility and a threshold voltage that are respectively high and low enough to achieve high current drivability. And if a crystalline semiconductor layer 107 is used as an active layer as is done in this preferred embodiment, the field-effect mobility and the threshold voltage achieved will be respectively higher and lower than those of the semiconductor layer 110, which is beneficial.

Furthermore, a switching TFT for use to switch a pixel electrode, for example, is required to have as small an amount of leakage current as possible in its OFF state and to have a high ON/OFF ratio. To realize these, it is effective to reduce the thickness of the semiconductor layer 107. This is because by reducing the thickness of the semiconductor layer 107, the S value of the TFT performance (i.e., the steepness of the rise in the amount of current to flow at a sub-threshold voltage) can be increased effectively even if the threshold voltage is low. However, if the semiconductor layer 107 were too thin, then the current value in ON state would decrease. That is why the semiconductor layer 107 preferably has a thickness of for example 30 nm to 60 nm.

As for a TFD, on the other hand, if the TFD is operating with a forward bias voltage applied, the semiconductor layer of the TFD should also have as high a degree of crystallinity and as small a thickness as possible just like the TFT. If a TFD is used as photosensor, however, the preferred crystal state and thickness of the semiconductor layer are different. When used as a photosensor, the TFD is turned OFF with a reverse bias voltage applied to sense an increase or decrease in leakage current when it is irradiated with light. In this case, the thicker the semiconductor layer, the higher the photosensitivity will be. Also, the increase or decrease in current can be detected with higher sensitivity by using an amorphous semiconductor layer rather than a crystalline semiconductor layer. For that reason, it is beneficial to use an amorphous semiconductor layer as the TFD's semiconductor layer 110 and make the semiconductor layer 110 thicker than the TFT's semiconductor layer 107.

In this preferred embodiment, the n-type or p-type region 114 or 118 and the source/drain regions 113 are preferably defined by the same doping process step. In that case, such a semiconductor device including a TFT and a TFD on the same substrate 101 can be fabricated by a simplified method and a simpler device structure can be obtained.

The semiconductor device 100 of this preferred embodiment has the following advantages over its counterparts disclosed in Patent Documents Nos. 2 and 3 mentioned above.

According to Patent Document No. 2, a portion of the same amorphous semiconductor film is selectively crystallized to form a semiconductor layer for a TFT of the crystallized portion and form a semiconductor layer for a TFD of the remaining amorphous portion of the film. However, as described above, it is difficult to realize a TFD that works fine as a photosensor by such a method. This is because some of the hydrogen atoms originally included in the amorphous silicon film will be lost during the heat treatment process step for crystallizing the portion of the amorphous silicon film into crystalline silicon.

Specifically, in an amorphous silicon film just deposited, those hydrogen atoms that have been absorbed there during the deposition process bond to the dangling bonds of Si atoms, thereby forming Si—H bonding and inactivating the Si dangling bonds in the amorphous silicon film. If the amorphous silicon film is thermally treated to be partially crystallized, that Si—H bonding will be broken and the dangling bonds of Si will get activated. The Si—H bonding energy can withstand a temperature of approximately 400° C. at most. That is why if a heat treatment is conducted at a temperature of 400° C. or more, that bonding will be broken and hydrogen atoms will be released. Once their bond with hydrogen atoms has been broken, the dangling bonds of Si will produce deep traps with respect to electrons or holes and will degrade the device performance of the TFT or TFD significantly. In a photosensor, among other things, the amount of current to flow in a dark environment (i.e., the dark current value) will fall steeply and the base will rise instead. In addition, the amount of current to flow in light (i.e., the bright current value) will also drop so much that the brightness to darkness ratio (i.e., the ratio of the bright current to the dark current) representing the performance of a photosensor will be too low to reach the practical level.

Patent Document No. 2 adopts a method for reproducing the Si—H bonding and inactivating the dangling bonds of Si by supplying hydrogen to the TFD's and TFT's semiconductor layer after the crystallization process. However, since the TFD's semiconductor layer, which is an amorphous silicon layer, includes a far greater number of dangling bonds than the crystalline silicon layer, it is very difficult to recover the original good state of the amorphous silicon layer just deposited.

Just like Patent Document No. 2, Patent Document No. 3 also has a similar problem. Specifically, according to Patent Document No. 3, the same amorphous silicon film is subjected to a half exposure process and a half etching process, thereby reducing the thickness of only a portion of the amorphous silicon film. After that, the amorphous silicon film is irradiated with a laser beam and only that portion with the reduced thickness is crystallized, thereby forming a silicon layer for a switching TFT. On the other hand, the thick portion of the amorphous silicon film (i.e., the portion that has not had its thickness reduced) remains amorphous and is used as a silicon layer for a photosensor TFT. According to such a method, when the amorphous silicon film is irradiated and crystallized with a laser beam, the radiation energy should be high enough to melt that thinned portion of the amorphous silicon film. That is why in that crystallization process step, hydrogen atoms will be activated by that high radiation energy and will be released from the thick portion of the amorphous silicon film. On top of that, if such high radiation energy is used, ablation might be produced in some parts of the film due to the release of those hydrogen atoms. To avoid such ablation, the amorphous silicon film should be either subjected to a heat treatment and dehydrated before irradiated with a laser beam or formed at as high a temperature as 400° C. or more. Thus, it is difficult to form an amorphous silicon layer of good quality as an active layer for the photosensor TFT.

On the other hand, according to this preferred embodiment, the TFT's semiconductor layer 107 and the TFD's semiconductor layer 110 are formed by patterning two different semiconductor films, and therefore, the crystal states of these semiconductor layers 107 and 110 can be optimized independently of each other. Specifically, in this preferred embodiment, it is preferred that an amorphous semiconductor film to be the TFT's semiconductor layer 107 (which will be referred to herein as “TFT's amorphous semiconductor film”) be deposited first and thermally treated and irradiated with a laser beam for the purpose of crystallization and then an amorphous semiconductor film to be the TFD's semiconductor layer 110 (which will be referred to herein as “TFD's amorphous semiconductor film”) be deposited on the gate insulating film 108. Then a semiconductor layer 110 that should work fine as an active layer for the TFD can be obtained without breaking the Si—H bonding of the TFD's amorphous semiconductor film. Once the amorphous semiconductor layer has been formed in this manner, the rest of the manufacturing process should not be carried out at as high a temperature as 400 or more. In that case, a semiconductor device can be completed without deteriorating the property of the amorphous semiconductor layer.

To simplify the manufacturing process, it is not beneficial to make the TFT's semiconductor layer 107 and the TFD's semiconductor layer 110 of two different layers. Compared to the method of Patent Document No. 3, however, the only additional process step according to this preferred embodiment is the step of forming the second semiconductor layer because an etching process step for reducing the thickness of a part of a silicon film should be performed additionally according to Patent Document No. 3. On top of that, according to Patent Document No. 3, the thickness of that thinned part of the silicon film would be determined by the precision of the etching process step and the thickness of the silicon film would vary significantly. On the other hand, according to this preferred embodiment, the respective thicknesses of the semiconductor films can be determined appropriately by performing the process step of forming the TFT's amorphous semiconductor film and the process step of forming the TFD's amorphous semiconductor film. Thus, the respective thicknesses of these amorphous semiconductor films can be controlled more easily and the variation in the thickness of each of these amorphous semiconductor films can be reduced considerably. That is to say, according to this preferred embodiment, the thickness d1 of the TFT's semiconductor layer (i.e., crystalline semiconductor layer) 107 is determined by the thickness of the TFT's amorphous semiconductor film and the thickness d2 of the TFD's semiconductor layer (i.e., amorphous semiconductor layer) 110 is determined by the thickness of the TFD's amorphous semiconductor film.

In this manner, according to this preferred embodiment, the thicknesses d1 and d2 of the TFT's and TFD's semiconductor layers 107 and 110 can be controlled independently of each other. It is preferred that the thickness d2 of the TFD's semiconductor layer 110 be set to be greater than the thickness d1 of the TFT's semiconductor layer 107. In that case, the TFT can have its ON/OFF ratio increased and its threshold voltage decreased, and therefore, can have its performance improved. As for the TFD, on the other hand, the bright current, representing the sensitivity of a photosensor, can be increased, thus improving the photosensor performance, too.

Particularly if the TFD is used as a photosensor, the thickness d2 of the TFD's semiconductor layer 110 is preferably greater than the sum (d1+d3) of the thickness d1 of the TFT's semiconductor layer 107 and the thickness d3 of the gate insulating film 108 (i.e., d2>d1+d3). Then the performance of the TFD can be further improved and the manufacturing process can be further simplified. The following is the reason.

If portions of the TFT's semiconductor layer (i.e., crystalline semiconductor layer) 107 to be source/drain regions 113 and a portion of the TFD's semiconductor layer (i.e., amorphous semiconductor layer) 110 to be an n-type region 114 or a p-type region 118 are doped at the same time, the TFD's semiconductor layer 110 could deteriorate due to the implantation damage caused. Specifically, the implantation damage could produce some heat to raise the temperature of the TFD's semiconductor layer 110. In that case, hydrogen atoms could be lost from the semiconductor layer 110 and the good hydrogenated amorphous state could no longer be maintained. Meanwhile, this doping process step needs to be performed on the TFT's semiconductor layer 107 under an optimized condition.

That is why if the thicknesses of the respective semiconductor layers 107 and 110 and the gate insulating film 108 are defined so as to satisfy the inequality d2>d1+d3, then the implantation process can be performed on the TFT's semiconductor layer 107 under the optimized condition with the damage done on the TFD's semiconductor layer 110 minimized using the thickness d3 of the gate insulating film 108.

Hereinafter, this point will be described in detail with reference to FIG. 1(b), which is a schematic cross-sectional view showing the concentration profiles (in the thickness direction) of the dopant that has been introduced into the semiconductor layers 107 and 110 in this preferred embodiment and also showing the temperature profiles of those semiconductor layers 107 and 110 during the doping process step.

In the example illustrated in FIG. 1(b), the TFT's semiconductor layer 107 is doped with an n-type or p-type dopant element that has passed through the gate insulating film 108 with the thickness d3 and such a doping process step will be referred to herein as a “through doping process”. On the other hand, the TFD's semiconductor layer 110 is doped with the dopant element directly (i.e., with no gate insulating film 108 interposed between them), and such a doping process step will be referred to herein as a “bare doping process”.

The concentration profile of the dopant element in the gate insulating film 108 and semiconductor layer 107 as measured in the depth direction under the upper surface of the gate insulating film 108 is represented by the curve Ct, while the temperature profile during the doping process step is represented by the curve Tt. On the other hand, the concentration profile of the dopant element in the semiconductor layer 110 as measured in the depth direction under the upper surface of the semiconductor layer 110 is represented by the curve Cd, while the temperature profile during the doping process step is represented by the curve Td. As can be seen from FIG. 1(b), if the semiconductor layers 107 and 110 are doped with the dopant element in the same doping process step, their concentration profiles Ct and Cd will be approximately equal to each other. That is why the depth Dt of the peak of the concentration profile Ct under the upper surface of the gate insulating film 108 is substantially equal to the depth Dd of the peak of the concentration profile Cd under the upper surface of the semiconductor layer 110. On the other hand, the temperature profiles Tt and Td vary according to the concentration profiles Ct and Cd and have their peaks in the vicinity of the depths Dt and Dd, respectively.

In this case, the doping process condition is preferably defined so that the depths Dt and Dd of those peaks satisfy d3<Dt and Dd<d1+d3. In that case, the peak of the concentration profile Ct will be located in the semiconductor layer 107, and therefore, the dopant concentration in the source/drain regions of the TFT can be increased and the ON-state resistance of the TFT can be reduced.

Also, if the respective thicknesses of these layers 107, 108 and 110 satisfy the inequality d1+d3<d2, the dopant can be introduced deep enough into the TFT's semiconductor layer (i.e., crystalline semiconductor layer) 107 and the source/drain regions can have reduced resistance. On the other hand, the dopant will not be introduced so deep into the TFD's semiconductor layer (i.e., hydrogenated amorphous semiconductor layer) 110 for its thickness d2. Consequently, the temperature of the semiconductor layer 110 will not be as high as that of the semiconductor layer 107. Among other things, the temperature at the bottom of the semiconductor layer 110 (i.e., at the interface between the semiconductor layer 110 and the gate insulating film 108) hardly rises and is kept low enough as a result of this doping process step. Consequently, the damage done on the semiconductor layer 110 can be reduced and the number of hydrogen atoms released due to the implantation damage can be minimized. By using the thickness of the gate insulating film d3 in this manner, both of these semiconductor layers 107 and 110 can meet their required doping process conditions at the same time.

It should be noted that if the thickness of the gate insulating film 108 is not uniform over the entire substrate 101, then the thickness d3 of the gate insulating film 108 is supposed to be measured over the source/drain regions 113 of the semiconductor layer 107.

In this preferred embodiment, the substrate 101 may be a light transmissive substrate (such as a glass substrate). In that case, an opaque layer (not shown) may be further arranged between the TFD's semiconductor layer 107 and the substrate 101.

If the TFD is used as a photosensor, the semiconductor layer 110 to be used as its active layer should be responsive to only external light. However, if this preferred embodiment is applied to a transmissive LCD in which a backlight is usually arranged on the back surface of its active-matrix substrate (corresponding to the substrate 101 in this example), an opaque layer is preferably arranged to face the backlight so as to prevent the TFD from sensing the light that has come from the backlight. That is to say, the opaque layer is arranged to shield the semiconductor layer 110 to be the TFD's active region from that light. Typically, the opaque layer is arranged between the semiconductor layer 110 and the substrate 101 so as to overlap with the semiconductor layer 110 at least partially. Also, part or all of the opaque layer is preferably made of the same film as the TFT's semiconductor layer. Then, the manufacturing process can be further simplified.

Hereinafter, a method for fabricating a semiconductor device according to this preferred embodiment will be described.

A manufacturing process according to this preferred embodiment includes the steps of: providing a substrate, of which the surface is already covered with a crystalline semiconductor film; patterning a portion of the crystalline semiconductor film into a first semiconductor island that will define the active region of a thin-film transistor; depositing a gate insulating film over the first semiconductor island; stacking an amorphous semiconductor film (i.e., an amorphous semiconductor film to form part of a TFD, which will be referred to herein as a “TFD amorphous semiconductor film”) on the gate insulating film; and patterning a portion of the TFD amorphous semiconductor film into a second semiconductor land that will define the active region of a thin-film diode.

It is preferred that the TFD amorphous semiconductor film be deposited more thickly than the crystalline semiconductor film. More preferably, the thickness of the TFD amorphous semiconductor film is set to be greater than the combined thickness of the crystalline semiconductor film and the gate insulating film. And in a specific preferred embodiment, the thickness of the TFD amorphous semiconductor film is preferably defined to be greater than the sum of the thickness of a portion of the crystalline semiconductor film that is not masked with the gate electrode on the gate insulating film and that of the gate insulating film itself.

By setting the thicknesses of the crystalline semiconductor film and the TFD amorphous semiconductor film as described above, the respective semiconductor layers of the TFT and the TFD can have their best characteristics expected separately in the TFT's channel region and in the TFD's intrinsic region. For example, if this preferred embodiment is applied to a display device with a photosensor, the TFTs for use to make a driver can have field-effect mobility and threshold voltage that are respectively high and low enough to achieve high current drivability, while the switching TFTs to function as switching elements for respective pixels will achieve excellent switching characteristic. On top of that, the TFD can also have a small amount of dark-state current and a large amount of bright-state current, thus achieving very good photosensor performance (i.e., a high bright-to-dark-state current ratio (or SNR)). What's more, according to this preferred embodiment, these two different types semiconductor components can be fabricated on the same substrate without significantly increasing the number of manufacturing processing steps and at a rather low manufacturing cost. Besides, since the TFT and the TFD are fabricated on the same substrate in parallel with each other, the overall size (e.g., area or thickness) of the semiconductor device can be much smaller than a situation where a TFT and a TFD are sequentially fabricated on a substrate, for example.

The manufacturing process of this preferred embodiment further includes, after the first and second semiconductor islands have been formed, the steps of: doping portions of the first semiconductor island to be source and drain regions with a dopant element from over and through the gate insulating film (which will be referred to herein as a “through doping process step”); doping a portion of the second semiconductor island to be an n-type region with an n-type dopant element directly (which will be referred to herein as a “bare doping process step”); and doping another portion of the second semiconductor island to be a p-type region with a p-type dopant element directly (which will be referred to herein as another “bare doping process step”).

By performing these process steps, n-type or p-type doped regions to be source/drain regions can be defined in the TFT's semiconductor layer and n-type and p-type doped regions can be defined in the TFD's semiconductor layer. As a result, the two different types of devices can be completed on the same substrate.

If the dopant element to be introduced into the portions of the first semiconductor island to be source/drain regions is an n-type dopant element, the through doping process step and the process step of introducing an n-type dopant element into a portion of the second semiconductor island to be an n-type region by bare doping are preferably performed simultaneously. By carrying out the doping process step to define the source/drain regions of an n-channel TFT and the doping process step to define the n-type doped region of a TFD as a single process step in this manner, the manufacturing process can be further simplified.

On the other hand, if the dopant element to be introduced into the portions of the first semiconductor island to be source/drain regions is a p-type dopant element, the through doping process step and the process step of introducing a p-type dopant element into a portion of the second semiconductor island to be a p-type region by bare doping are preferably performed simultaneously. By carrying out the doping process step to define the source/drain regions of a p-channel TFT and the doping process step to define the p-type doped region of a TFD as a single process step in this manner, the manufacturing process can be further simplified.

According to this preferred embodiment, the first semiconductor island may include islands of semiconductor regions including islands to be the respective active regions of n-channel and p-channel thin-film transistors. In that case, the first semiconductor island that will form part of an n-channel thin-film transistor is doped with an n-type dopant element first, and then the first semiconductor island that will form part of a p-channel thin-film transistor is doped with a p-type dopant element. Of these process steps, the process step of introducing an n-type dopant element into portions of the first semiconductor island to be the source/drain regions of an n-channel thin-film transistor by through doping and the process step of introducing an n-type dopant element into a portion of the second semiconductor island to be an n-type region are preferably performed simultaneously. Likewise, the process step of introducing a p-type dopant element into portions of the first semiconductor island to be the source/drain regions of a p-channel thin-film transistor by through doping and the process step of introducing a p-type dopant element into a portion of the second semiconductor island to be a p-type region are preferably performed simultaneously.

In that case, when a TFT circuit with a CMOS configuration is formed, a doping process step to define the source/drain regions of its n-channel TFT and a doping process step to define the n-type doped region of its TFD can be performed as a single process step. Likewise, a doping process step to define the source/drain regions of its p-channel TFT and a doping process step to define the p-type doped region of its TFD can also be performed as a single process step. As a result, the manufacturing process can be simplified significantly.

In the process step of doping the first and second semiconductor islands at the same time, the effect that has already been described with reference to FIG. 1(b) can be achieved as long as the thickness d1 of the first semiconductor island (i.e., the thickness of the crystalline semiconductor film), the thickness d3 of the gate insulating film, and the thickness d2 of the second semiconductor island (i.e., the thickness of the TFD amorphous semiconductor film) satisfy the inequality d1+d3<d2. Specifically, the first semiconductor island to be the TFT's active region can be doped to a sufficient implant depth to reduce the resistance in the source/drain regions. On the other hand, the second semiconductor island to be the TFD's active region has a relatively moderate implant depth for its thickness d2 and will have a lighter doping damage. As a result, it is possible to prevent hydrogen atoms in the second semiconductor island from being desorbed, and therefore, good hydrogenated amorphous state can be maintained. In this manner, the doping conditions for the respective semiconductor layers can be satisfied at the same time. Consequently, a semiconductor device including, on the same substrate, a TFT and a TFD, of which the properties of the semiconductor layers have been optimized according to their respective applications, can be provided at a reduced manufacturing cost without increasing the number of manufacturing process steps.

According to the manufacturing process of this preferred embodiment, the step of doping a portion of the second semiconductor island to be an n-type region with an n-type dopant element and the step of doping a portion of the second semiconductor island to be a p-type region with a p-type dopant element are preferably performed so that a portion doped with no dopant elements in any of those doping process steps (i.e., a intrinsic region) is left between those portions of the second semiconductor island to be n-type and p-type regions.

The manufacturing process of this preferred embodiment preferably further includes the step of irradiating those portions of the first semiconductor island, which are not masked with the gate electrode, with a laser beam through the gate insulating film, thereby activating the n-type or p-type dopant in the first semiconductor island. In this process step, it is particularly preferred that the thickness d3 (nm) of those portions of the gate insulating film that are not masked with the gate electrode satisfy d3=m×λ/(4×n)±15 nm (where m is an integer that is equal to or greater than one and may be 1, 2, 3 and so on) with respect to the wavelength λ (nm) of the laser beam and the refractive index n of the gate insulating film. Hereinafter, the reason will be described in detail.

To minimize the number of hydrogen atoms to be desorbed from the hydrogenated amorphous semiconductor layer that is the TFD's semiconductor layer, it is preferred that the process that follows the doping process step be performed at a temperature of 400° C. or less. The step of activating the dopant that has been introduced into the source/drain regions should be performed at a higher temperature than any other one of a number of process steps that follow the doping process step. To perform the activating process step with the temperature of the substrate kept less than 400° C., it is preferred that the activation be done by irradiating the semiconductor layer with a laser beam without heating the substrate directly as described above. However, even if the activation is done by irradiating the semiconductor layer with a laser beam, the TFD's hydrogenated amorphous semiconductor layer is also exposed to the laser beam, and therefore, hydrogen atoms could still leave the layer. For that reason, the laser irradiation process should be performed with as low energy as possible. That is why the thickness d3 of the gate insulating film is used again. More specifically, the gate insulating film is used as a sort of antireflective film against the laser beam so that only the semiconductor layer under the gate insulating film (i.e., the first semiconductor island) is heated effectively. In that case, the thickness d3 (nm) of the gate insulating film that functions most effectively as an antireflective film is represented by the following equation:

d3=m×λ/(4×n)

where m is an integer that is equal to or greater than one and may be 1, 2, 3 and so on, n is the refractive index of the gate insulating film and λ is the wavelength (nm) of the laser beam.

If a normal silicon dioxide film (with a refractive index n of 1.46) is used as the gate insulating film, if an XeCl excimer laser beam with a wavelength of 308 nm is used as the laser beam, and if the gate insulating film has a thickness d3 of 53.7 nm or 105.4 nm, then the antireflection effect of the gate insulating film can be maximized locally. And if the thickness d3 of the gate insulating film falls within the range of ±15 nm with respect to that thickness to maximize the effect locally, the effective energy of the laser beam radiated can have a significant difference between the first semiconductor island that is covered with the gate insulating film and the second semiconductor island that is not covered with the gate insulating film.

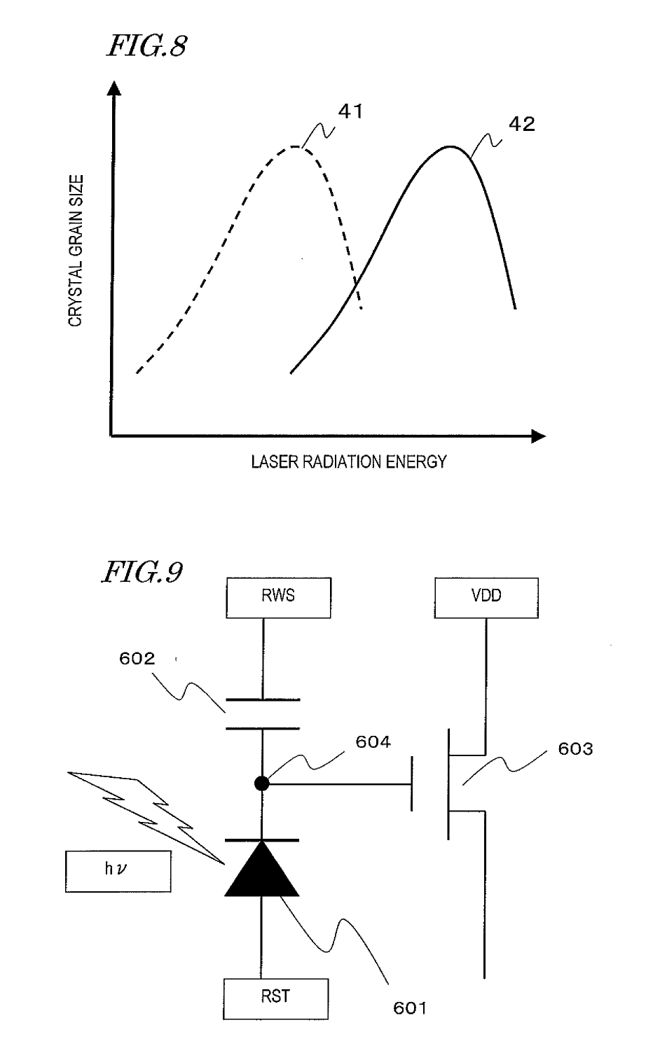

FIG. 8 shows correlations between the crystal grain size and the energy of a laser beam radiated in the crystal-growing process using the laser beam. In FIG. 8, the curve 42 shows how the size of the crystal gains in the amorphous silicon film being crystallized by being irradiated with a laser beam directly with no gate insulating film interposed changes with the energy of the laser beam radiated. On the other hand, the curve 41 shows how the size of the crystal gains in the amorphous silicon film being crystallized by being irradiated with a laser beam that has come from over, and through, a silicon dioxide film that has been deposited to a thickness of 54 nm on the amorphous semiconductor film changes with the energy of the laser beam radiated. In any of these two kinds of crystal-growing processes represented by the curves 41 and 42, the higher the energy of the laser beam radiated, the greater the crystal grain size tends to be. However, each of these curves reaches an extreme value at some point. And if the energy of the laser beam radiated goes beyond that, the crystal grain size decreases to the contrary. Also, the curve 41 is in a lower energy range than the curve 42. As can be seen from the curve 41 shown in FIG. 8, the silicon dioxide film functions as an antireflection film against the incoming laser beam, the effective energy of the laser beam that irradiates the amorphous silicon film rises, and the optimum value of the energy radiated shifts toward a low energy range. In this example, the crystal-growing process using a laser beam has been described. However, a similar antireflection effect can also be achieved in the activation process using a laser beam.

As the effective energy can be increased by the antireflection effect of the gate insulating film, the source/drain regions in the TFT's semiconductor layer can be activated efficiently with lower radiation energy. On the other hand, since the TFD's semiconductor layer (i.e., the hydrogenated amorphous semiconductor layer) is not covered with any antireflection film, the effective radiation energy is not raised. On top of that, the TFD's semiconductor layer is thicker, and therefore, has a greater heat capacity, than the TFT's semiconductor layer. As a result, desorption of hydrogen atoms from the TFD's semiconductor layer can be minimized and a good hydrogenated amorphous semiconductor state can be maintained.

In this preferred embodiment, the substrate may be a light-transmissive substrate. In that case, the manufacturing process of this preferred embodiment preferably further includes the step of forming an opaque layer for cutting light that has come from under the opposite surface of the substrate on a region of the substrate, which will be located under the second semiconductor island to be the active region of a thin-film diode. With such an opaque layer provided, the light emitted from a backlight from under the opposite surface of the substrate can be cut off effectively in a liquid crystal display device, for example, and the TFD can sense only the light coming from over the device efficiently. More preferably, by patterning the crystalline semiconductor film, a first semiconductor island to be the active region of a thin-film transistor and at least a part of the opaque layer are formed simultaneously. Then, the manufacturing process can be further simplified.

According to this preferred embodiment, the crystalline semiconductor film may also be formed by performing the steps of: providing a substrate, of which the surface is already covered with an amorphous semiconductor film (i.e., a TFT's amorphous semiconductor film); and irradiating and crystallizing the TFT's amorphous semiconductor film with a laser beam. Then, a crystalline semiconductor film with an excellent degree of crystallinity can be obtained and the performance of the TFT can be enhanced.

It is more preferred that the crystalline semiconductor film be formed by performing the steps of: providing a substrate, of which the surface is already covered with a TFT's amorphous semiconductor film; adding a catalyst element, which promotes crystallization, to the TFT's amorphous semiconductor film; and heating and crystallizing the TFT's amorphous semiconductor film to which the catalyst element has been added. If a metallic element that promotes crystallization is added to the TFT's amorphous semiconductor film and then the amorphous semiconductor film is heated and crystallized, a crystalline semiconductor film of better quality, of which the crystals are aligned more perfectly than a normal crystalline semiconductor film that has been crystallized just by being irradiated with a laser beam, can be obtained. And by using such a crystalline semiconductor film of quality as the active region of a TFT, the performance of the TFT can be further enhanced.

### Embodiment 1

Hereinafter, a First Preferred Embodiment of a semiconductor device according to the present invention will be described. The semiconductor device of this preferred embodiment includes an n-channel TFT and a TFD on the same substrate and may be used as an active-matrix-addressed display device with a sensor section, for example.

FIG. 2 is a schematic cross-sectional view illustrating an exemplary semiconductor device according to this preferred embodiment. The semiconductor device of this preferred embodiment typically includes a number of TFTs and a number of TFDs on the same substrate. In FIG. 2, however, the configurations of just one of those TFTs and only one of those TFDs are illustrated.

The semiconductor device of this preferred embodiment includes a thin-film transistor 124 and a thin-film diode 125, which are arranged on a substrate 101 with undercoat films 103 and 104 interposed between them. The thin-film transistor 124 includes a semiconductor layer 107 with a channel region 115 and source/drain regions 113, a gate insulating film 108 on the semiconductor layer 107, a gate electrode 109 that controls the conductivity of the channel region 115, and electrodes and interconnects 122 that are connected to the source/drain regions 113. On the other hand, the thin-film diode 125 includes a semiconductor layer 110 with at least an n-type region 114 and a p-type region 118 and electrodes and interconnects 123 that are connected to the n- and p-type regions 114 and 118. The semiconductor layer 110 of the thin-film diode 125 has been deposited on, and is in contact with, the upper surface of the gate insulating film 108. Also, in the example illustrated in FIG. 2, an intrinsic region 119 is defined between the n- and p-type regions 114 and 118 of the semiconductor layer 110.

The thin-film transistor 124 and the thin-film diode 125 are coated with a silicon nitride film 120 and a silicon dioxide film 121 as interlevel dielectric films. Also arranged between the semiconductor layer 110 of the thin-film diode 125 and the substrate 101 is an opaque layer 102.

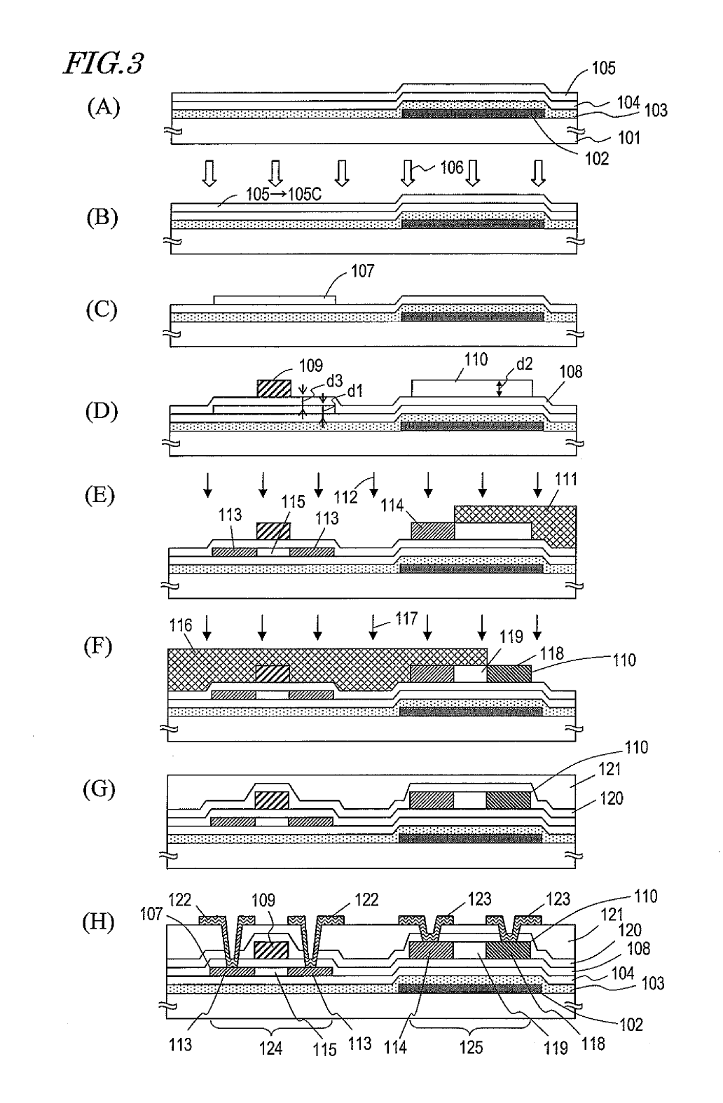

The respective semiconductor layers 107 and 110 of the thin-film transistor 124 and the thin-film diode 125 have been formed by patterning two different semiconductor films. That is to say, the semiconductor layer 107 of the thin-film transistor 124 is a crystalline semiconductor layer, while the semiconductor layer 110 of the thin-film diode 125 is an amorphous semiconductor layer. In this case, the semiconductor layer 110 of the thin-film diode 125 is thicker than its counterpart 107 of the thin-film transistor 124. In the example illustrated in FIG. 3, the thickness of the semiconductor layer 110 of the thin-film diode 125 is greater than the sum of the respective thicknesses of the semiconductor layer 107 and the gate insulating film 108 of the thin-film transistor 124.

The n-channel thin-film transistor 124 and the thin-film diode 125 shown in FIG. 2 may be fabricated in the following procedure, for example.

FIGS. 3(A) through 3(H) are cross-sectional views illustrating the respective process steps to fabricate the thin-film transistor 124 and the thin-film diode 125 of this preferred embodiment. These process steps are carried out in the same order that these portions (A) through (H) of FIG. 3 are arranged.

First of all, as shown in FIG. 3(A), an opaque layer 102, a first undercoat film 103, a second undercoat film 104 and an amorphous semiconductor film 105 are stacked in this order on the surface of the substrate 101 on which a TFT and a TFD are going to be fabricated.

A low alkali glass substrate or a quartz substrate may be used as the substrate 101. In this preferred embodiment, a low alkali glass substrate is used. In that case, the glass substrate may be heat-treated in advance to a temperature that is lower than the glass stain point by about 10-20° C.

The opaque layer 102 is arranged so as to prevent the light that has come from under the back surface of the substrate from entering the TFD in the final product. The opaque layer 102 may be made of a metal film or a silicon film, for example. If a metal film is used, a refractory metal such as tantalum (Ta), tungsten (W) or molybdenum (Mo) is preferred considering the heat treatment to be carried out at a later stage of the manufacturing process. In this preferred embodiment, a Mo film is deposited by sputtering process and then patterned, thereby forming the opaque layer 102. In this case, the opaque layer 102 may have a thickness of 30 nm to 200 nm and preferably has a thickness of 50 nm to 150 nm (e.g., 100 nm in this preferred embodiment).

The undercoat films 103 and 104 may be made of silicon dioxide, silicon nitride or silicon oxynitride, for example, to prevent impurities from diffusing from the substrate 101. In this preferred embodiment, a silicon oxynitride film is deposited as the lower, first undercoat film 103 by performing a plasma CVD process with source gases of SiH₄, NH₃ and N₂O supplied, and then a second undercoat film 104 is deposited thereon by performing a plasma CVD process again with source gases of SiH₄ and N₂O supplied. In this case, the silicon oxynitride film as the first undercoat film 103 has a thickness of 30 nm to 400 nm (e.g., 200 nm) and the silicon dioxide film as the second undercoat film 104 has a thickness of 50 nm to 300 nm (e.g., 100 nm). Although a two-layered undercoat film is used in this preferred embodiment, a single layer of silicon dioxide may also be used.

Next, a silicon film with an amorphous structure (i.e., an a-Si film) is formed as the amorphous semiconductor film 105 by a known process such as a plasma CVD process or a sputtering process. The a-Si film 105 may have a thickness of 20 nm to 100 nm (preferably in the range of 30 nm to 70 nm). In this preferred embodiment, an a-Si film 105 is deposited to a thickness of 50 nm by plasma CVD process. Optionally, the undercoat films 103 and 104 and the amorphous silicon film 105 may be deposited continuously because these films can be formed by the same deposition process. If the substrate on which the undercoat films have been deposited is not exposed to the air, contamination on its surface can be avoided and variations in characteristic or the threshold voltage between the TFTs to fabricate can be minimized.

Next, the a-Si film 105 is heated to a temperature of 400 to 550° C. for several ten minutes to several hours, thereby releasing hydrogen atoms from the a-Si film 105. Subsequently, as shown in FIG. 3(B), the a-Si film 105 is irradiated with a laser beam 106. The a-Si film 105 is melted when irradiated with the laser beam 106 but soon gets solidified and crystallized to turn into a crystalline silicon film 105c eventually.

In this preferred embodiment, before being irradiated and crystallized with a laser beam, the a-Si film 105 is subjected to a heat treatment in advance to release hydrogen atoms. This is a preferred method because an a-Si film that has been deposited by a normal CVD process includes so many hydrogen atoms that those hydrogen atoms would suddenly pop out of the film and cause ablation if the a-Si film in such a state were irradiated with a laser beam as it is.

In this process step, an XeCl excimer laser beam (with a wavelength of 308 nm) or a KrF excimer laser beam (with a wavelength of 248 nm) may be used as the laser beam 106. Also, in this process step, the sizes of the laser beam spot 106 are determined so that an elongated beam spot is formed on the surface of the substrate 101. And by sequentially scanning the surface of the substrate 101 perpendicularly to the direction in which the beam spot is elongated, the amorphous silicon film gets crystallized over the entire surface of the substrate. In this case, if the surface is scanned so that the beam spots partially overlap with each other, an arbitrary point on the a-Si film 105 will be irradiated with the laser beam a number of times, thus contributing to increasing the uniformity. In this preferred embodiment, the sizes of the beam spot are determined so that the beam spot has an elongated shape of 300 mm×0.4 mm on the surface of the substrate 101 and the substrate is sequentially scanned at a step of 0.02 mm perpendicularly to the direction in which the beam spot is elongated. That is to say, any arbitrary point on the silicon film gets irradiated with the laser beam 20 times in total. Examples of laser beams that can be used in this process step include KrF and XeCl excimer laser beams of pulsed or continuous wave type described above but also a YAG laser beam or a YVO4 laser beam as well. Also, in this process step, the silicon film may be irradiated with the laser beam with an energy density of 250 to 450 mJ/cm², e.g., 350 mJ/cm².

Thereafter, excessive portions of the crystalline silicon film 105c are removed, thereby electrically isolating these two element regions from each other as shown in FIG. 3(C). As a result, a semiconductor island 107 to be the active region (including source/drain regions and a channel region) of a TFT is obtained.

Subsequently, as shown in FIG. 3(D), a gate insulating film 108 is deposited over the semiconductor island 107. Thereafter, a metallic electrode to be the gate electrode 109 of a TFT and another semiconductor island 110 to define the active region of a TFD (including an n-type region, a p-type region and an intrinsic region) are formed thereon.

The gate insulating film 108 is preferably a silicon dioxide film with a thickness of 20 nm to 150 nm. In this preferred embodiment, a silicon dioxide film with a thickness of 100 nm was used.

The gate electrode 109 may be formed by depositing a conductive film on the gate insulating film 108 by sputtering or CVD process, for example, and then patterning it. The conductive film to deposit in this process step is preferably a refractory metal such as W, Ta, Ti or Mo or an alloy thereof, and preferably has a thickness of 300 nm to 600 nm. In this preferred embodiment, a molybdenum (Mo) film was deposited to a thickness of 450 nm as the conductive film.

The semiconductor island 110 may be formed by depositing a second amorphous silicon film on the gate insulating film 108 and then patterning it. The second amorphous silicon film may be deposited by performing a plasma CVD process with SiH₄ supplied as a source gas and with the substrate heated to a temperature of 250° C. to 400° C. According to such a method, a hydrogenated amorphous silicon film of quality, in which the dangling bonds of Si atoms have been terminated with hydrogen atoms, can be obtained.

In this process step, the thickness d2 of the semiconductor island 110 is preferably set to be greater than the thickness d1 of the semiconductor layer 107 (which may be 50 nm in this example) to define the active region of the TFT. More particularly, the thickness d2 is preferably defined to be greater than the sum (of 150 nm in this example) of the thickness d3 of the gate insulating film 108 (which may be 100 nm in this example) and the thickness d1 of the semiconductor layer 107. In this example, the semiconductor island 110 is supposed to have a thickness d2 of 250 nm.

Thereafter, as shown in FIG. 3(E), a photoresist mask 111 is formed so as to partially cover the semiconductor island 110 to be the active region of a TFD, and ions 112 of an n-type dopant (such as phosphorus) are implanted into the entire surface of the substrate 101 from over it. This ion implantation process step is carried out so that the phosphorus ions 112 pass through the gate insulating film 108 to reach the semiconductor island 107 to be the active region of a TFT but that the semiconductor island 110 to be the active region of a TFD is laid bare (i.e., exposed) to the phosphorus ions 112. As a result of this process step, the phosphorus ions 112 are implanted into the exposed portion of the TFD's semiconductor island 110, which is not covered with the photoresist mask 111, and into that of the TFT's semiconductor layer 107, which is not masked with the gate electrode 109. However, the phosphorus ions 112 are implanted into neither the portion that is covered with the photoresist mask 111 nor the portion that is masked with the gate electrode 109. Consequently, those portions of the TFT's semiconductor island 107, which have been implanted with the phosphorus ions 112, will be the source/drain regions 113 of the TFT, while the portion masked with the gate electrode 109 and implanted with no phosphorus ions 112 will be the channel region 115 of the TFT. On the other hand, the portion of the TFD's semiconductor island 110, which has been implanted with the phosphorus ions 112, will be the n-type region (i.e., n⁺ region) 114 of the TFD.

In this case, the respective thicknesses d1, d2 and d3 of the semiconductor layers 107 and 110 and the gate insulating film 108 do satisfy d1+d3<d2. That is why the semiconductor island 107 to be the TFT's active region can be doped to a sufficient implant depth to reduce the resistance in the source/drain regions 113. On top of that, as the semiconductor layer 107 is heated during the implantation process, the dopant implanted will activate itself under the heat, too. On the other hand, the hydrogenated semiconductor layer 110 to be the TFD's active region has a relatively moderate implant depth for its thickness d2 and will have a lighter doping damage. Furthermore, the semiconductor layer 110 is so thick and such a great heat capacity that the temperature of the semiconductor layer 110 will not rise as steeply as that of the semiconductor layer 107. As a result, the implantation damage and desorption of hydrogen atoms due to a rise in temperature during the implantation process can be both minimized.

Next, the photoresist mask 111 used in the previous process step is stripped and then another photoresist mask 116 is formed so as to cover a part of the semiconductor island 110 to be the active region of a TFD and the entire semiconductor island 107 to be the active region of a TFT, and ions 117 of a p-type dopant (such as boron) are implanted into the entire surface of the substrate 101 from over it as shown in FIG. 3(F). As a result of this process step, the boron ions 117 are implanted into the exposed portion of the TFD's semiconductor island 110, which is not covered with the photoresist mask 116. That is to say, no boron ions 117 are introduced into the regions covered with the photoresist mask 116. Consequently, that portion of the TFD's semiconductor island 110, which has been implanted with the boron ions 117, will be the p-type (i.e., p⁺ region) 118 of the TFD, while the portion that has been implanted with no phosphorus ions in the previous process step and no boron ions in this process step, either, will be the intrinsic region 119 thereof.

Subsequently, the photoresist mask 116 is stripped and then a silicon dioxide film and/or a silicon nitride film is/are deposited as an interlevel dielectric film 120, 121 as shown in FIG. 3(G). In this preferred embodiment, the interlevel dielectric film has a dual layer structure consisting of a silicon nitride film 120 and a silicon dioxide film 121. The silicon nitride film 120 can function as a barrier layer against hydrogen, and therefore, can minimize desorption of hydrogen atoms from the TFD's semiconductor layer 110 of hydrogenated amorphous silicon. Then, after the interlevel dielectric film has been deposited, a heat treatment is carried out within an inert atmosphere (such as a nitrogen atmosphere). The heat treatment temperature is preferably not excessively high to minimize desorption of hydrogen atoms from the semiconductor layer 110 of hydrogenated amorphous silicon. In this preferred embodiment, the heat treatment is carried out at a temperature of 350 to 450° C. for several ten minutes to one hour, for example. As a result of this heat treatment, the phosphorus and boron atoms that have been introduced into the portions to be TFT's source/drain regions 113 and TFD's n⁺ and p⁺ regions 114 and 118 are activated.

After that, as shown in FIG. 3(H), contact holes are cut through the interlevel dielectric films 120 and 121 of silicon nitride and silicon dioxide and a metallic material is deposited thereon and patterned into electrodes and interconnects 122 and 123 to form parts of a TFT and a TFD. In this manner, a thin-film transistor 124 and a thin-film diode 125 are completed. Optionally, to protect these components, a passivation film of silicon nitride, for example, may be deposited over the thin-film transistor 124 and the thin-film diode 125.

According to this method, the respective semiconductor layers of a TFT and a TFD (more particularly, the TFT's channel region and the TFD's intrinsic region) can be formed to have ideal shapes and properties. As a result, the TFT and photosensor TFD can achieve their best performances just as expected.

### Embodiment 2

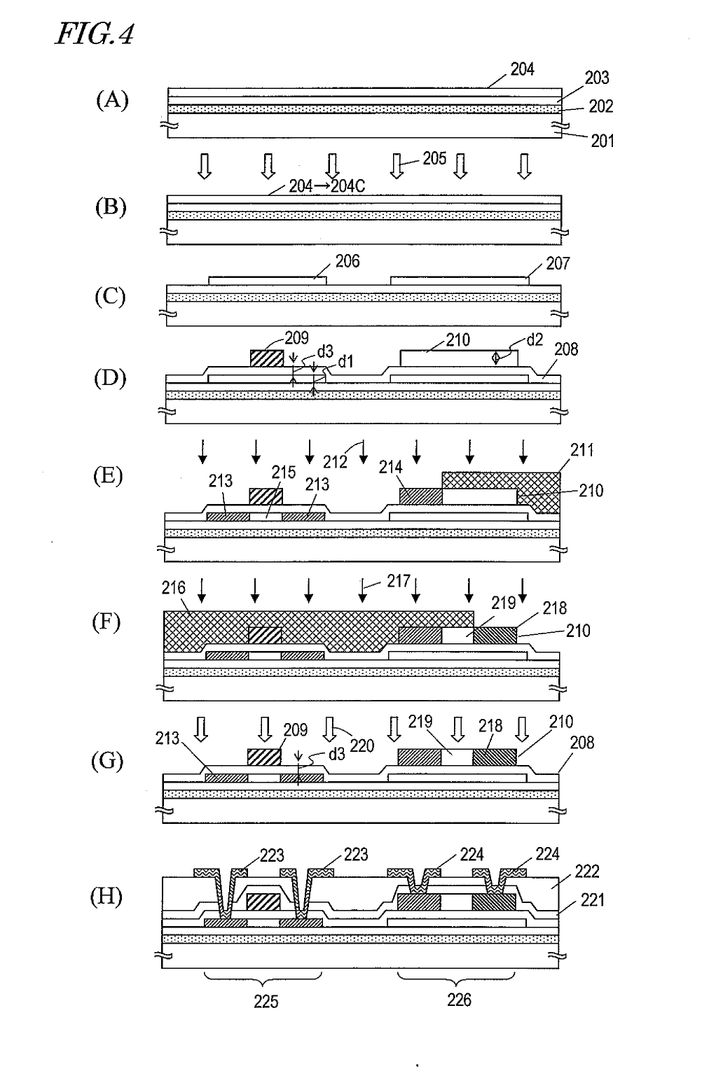

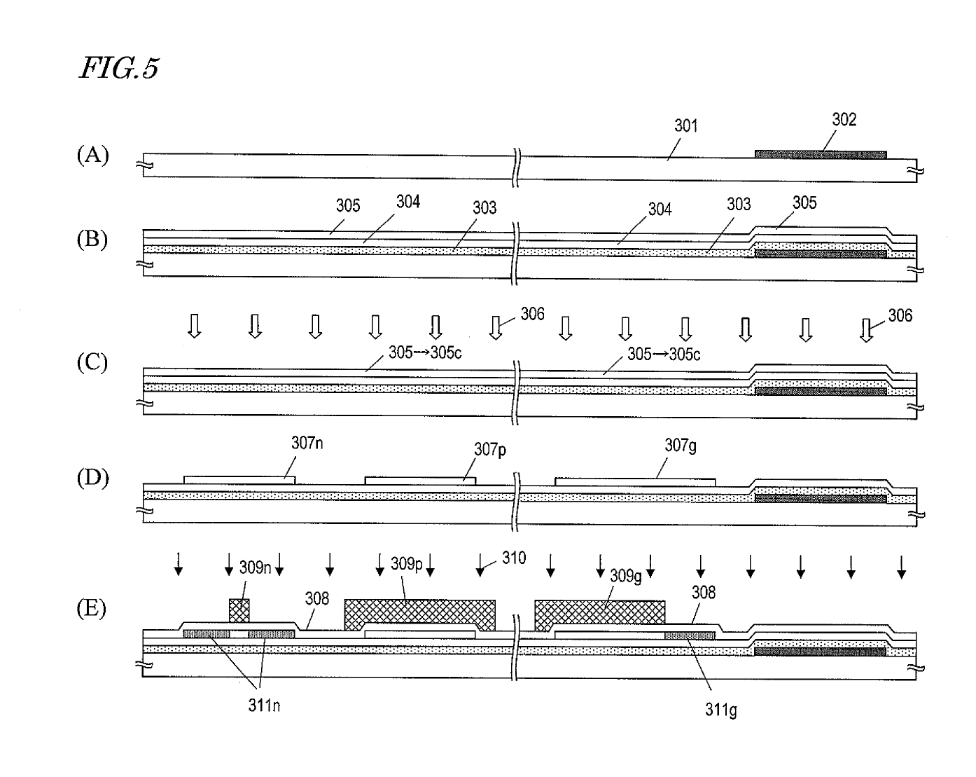

Hereinafter, a second preferred embodiment of a semiconductor device according to the present invention will be described with reference to FIG. 4. Specifically, it will be described how to form TFT's and TFD's semiconductor layers at the same time on a glass substrate by a different method from the one adopted in the first preferred embodiment described above. FIG. 4 illustrates cross-sectional views showing the respective process steps to fabricate a thin-film transistor 225 and a thin-film diode 226. These process steps are carried out in the same order that these drawings (i.e., from FIG. 4(A) through 4(H)) are arranged.

First, as shown in FIG. 4(A), first and second undercoat films 202 and 203 are formed in this order on a substrate 201 (which may be a glass substrate according to this preferred embodiment) as in the first preferred embodiment of the present invention described above to prevent impurities from diffusing from the substrate. In this preferred embodiment, the first and second undercoat films 202 and 203 are made of silicon nitride and silicon dioxide, respectively. Next, an amorphous silicon film 204 is deposited to a thickness of 30-80 nm (e.g., 50 nm). In this process step, the undercoat insulating films 202, 203 and the amorphous semiconductor film 204 may be deposited continuously without exposing them to the air.

Subsequently, as shown in FIG. 4(B), the amorphous silicon film 204 is irradiated with a laser beam 205. In this process step, an XeCl excimer laser beam (with a wavelength of 308 nm) may be used as the laser beam 205 as in the first preferred embodiment described above. In this case, if the surface is scanned so that the beam spots partially overlap with each other, an arbitrary point on the silicon film will be irradiated with the laser beam a number of times. In that case, the amorphous silicon film 204 can be crystallized more uniformly, which is beneficial. As a result of this process step, the amorphous silicon film 204 gets crystallized by going through a melting and solidification process by being irradiated with the laser beam 205 and turns into a crystalline silicon film 204c. If necessary, before being irradiated with the laser beam 205, the amorphous silicon film 204 may be heated to a temperature of 400 to 550° C. for several ten minutes to several hours in order to release hydrogen atoms from the amorphous silicon film 204.

Thereafter, excessive portions of the crystalline silicon film 204c are removed, thereby electrically isolating these two element regions from each other as shown in FIG. 4(C). As a result, a semiconductor island 206 to be the TFT's active region (including source/drain regions and a channel region) and a semiconductor island 207 to be the TFD's active region are obtained. The opaque layer 207 is arranged so as to prevent the light that has come from under the back surface of the substrate from entering the TFD in the final product.

Subsequently, as shown in FIG. 4(D), a gate insulating film 208 is deposited over the semiconductor islands 206 and 207 to be the TFT's active region and the TFD's opaque layer, respectively. Thereafter, a metallic electrode to be the gate electrode 209 of a TFT and another semiconductor island 210 to define the active region of a TFD (including an n-type region, a p-type region and an intrinsic region) are formed thereon. The gate electrode-to-be 209 and the semiconductor island 209 may be formed in any order.

The gate insulating film 208 is preferably a silicon dioxide film with a thickness of 20 nm to 150 nm. In this preferred embodiment, a silicon dioxide film with a thickness of 105 nm was used.

The gate electrode 209 may be formed by depositing a conductive film on the gate insulating film 208 by sputtering or CVD process, for example, and then patterning it. In this preferred embodiment, the conductive film to deposit may be made of a low-melting metal. In this example, an inexpensive Al alloy with low resistance is used. An Al alloy is obtained by adding about 0.2% to about 3% of Si, Ti, Nd and other elements to pure Al and has higher thermal resistance than pure Al. Specifically, in this preferred embodiment, an Al—Nd alloy film is deposited to a thickness of 400 nm, for example, as the conductive film.

The semiconductor island 210 may be formed by depositing a second amorphous silicon film on the gate insulating film 108 and then patterning it. The second amorphous silicon film may be deposited by performing a plasma CVD process with SiH₄ supplied as a source gas and with the substrate heated to a temperature of 250° C. to 400° C. According to such a method, a hydrogenated amorphous silicon film of quality, in which the dangling bonds of Si atoms have been terminated with hydrogen atoms, can be obtained. In this process step, the thickness d2 of the semiconductor island 210 is preferably set to be greater than the thickness d1 of the semiconductor layer 206 (which may be 50 nm in this example) to define the active region of the TFT. More particularly, the thickness d2 is preferably defined to be greater than the sum (of 155 nm in this example) of the thickness d3 of the gate insulating film 208 (which may be 105 nm in this example) and the thickness d1 of the semiconductor layer 206. In this example, the semiconductor island 210 is supposed to have a thickness d2 of 400 nm.

Thereafter, as shown in FIG. 4(E), a photoresist mask 211 is formed so as to partially cover the semiconductor island 210 to be the active region of a TFD, and ions 212 of an n-type dopant (such as phosphorus) are implanted into the entire surface of the substrate 201 from over it. This ion implantation process step is carried out so that the phosphorus ions 212 pass through the gate insulating film 208 to reach the semiconductor island 206 to be the active region of a TFT but that the semiconductor island 210 to be the active region of a TFD is laid bare (i.e., exposed) to the phosphorus ions 212. As a result of this process step, the phosphorus ions 212 are implanted into the exposed portion of the TFD's semiconductor island 210, which is not covered with the photoresist mask 211, and into that of the TFT's semiconductor layer 206, which is not masked with the gate electrode 209. However, the phosphorus ions 212 are implanted into neither the portion that is covered with the photoresist mask 211 nor the portion that is masked with the gate electrode 209. Consequently, those portions of the TFT's semiconductor island 206, which have been implanted with the phosphorus ions 212, will be the source/drain regions 213 of the TFT, while the portion masked with the gate electrode 209 and implanted with no phosphorus ions 212 will be the channel region 215 of the TFT. On the other hand, the portion of the TFD's semiconductor island 210, which has been implanted with the phosphorus ions 212, will be the n⁺ region 214 of the TFD.

In this preferred embodiment, the respective thicknesses d1, d2 and d3 of the semiconductor layers 206 and 210 and the gate insulating film 208 also satisfy d1+d3<d2 as in the first preferred embodiment described above. That is why the semiconductor island 206 to be the TFT's active region can be doped to a sufficient implant depth to reduce the resistance in the source/drain regions 213. On top of that, as the semiconductor layer 107 is heated during the implantation process, the dopant implanted will activate itself under the heat, too. On the other hand, the hydrogenated amorphous semiconductor layer 210 to be the TFD's active region has a lighter doping damage. Furthermore, the semiconductor layer 210 has such a great heat capacity that the temperature of the semiconductor layer 210 will not rise so steeply. As a result, the implantation damage and desorption of hydrogen atoms due to a rise in temperature during the implantation process can be both minimized.

Next, the photoresist mask 211 is stripped and then another photoresist mask 216 is formed so as to cover a part of the semiconductor island 210 to be the active region of a TFD and the entire semiconductor island 206 to be the active region of a TFT, and ions 217 of a p-type dopant (such as boron) are implanted into the entire surface of the substrate 201 from over it as shown in FIG. 4(F). As a result of this process step, the boron ions 217 are implanted into the exposed portion of the TFD's semiconductor island 210, which is not covered with the photoresist mask 216. That is to say, no boron ions 217 are introduced into the regions covered with the photoresist mask 216. Consequently, that portion of the TFD's semiconductor island 210, which has been implanted with the boron ions 217, will be the p⁺ region 218 of the TFD, while the portion that has been implanted with no phosphorus ions in the previous process step and no boron ions 217 in this process step, either, will be the intrinsic region 219 thereof.

Subsequently, the photoresist mask 216 is stripped and then these layers are irradiated with a laser beam 220 that has come from over the substrate 201 as shown in FIG. 4(G). The laser beam 220 may be radiated as in the crystallization process step described above. An XeCl excimer laser beam (with a wavelength of 308 nm) may be used as the laser beam 220. Also, in this process step, the sizes of the laser beam spot 220 are determined so that an elongated beam spot is formed on the surface of the substrate 201. And by sequentially scanning the surface of the substrate 201 perpendicularly to the direction in which the beam spot is elongated, the entire surface of the substrate can be irradiated. In this case, if the surface is scanned so that the beam spots partially overlap with each other, an arbitrary point on the substrate will be irradiated with the laser beam a number of times, thus contributing to increasing the uniformity in predetermined regions of the semiconductor layers 206 and 210.

As can be seen from FIG. 4(G), in this process step, the exposed portions of the TFT's semiconductor layer 206 (i.e., source/drain regions 213), which are not masked with the gate electrode 209, are irradiated with the laser beam 220 that has passed through the gate insulating film 208 with the thickness d3. On the other hand, the TFD's semiconductor layer 210 is directly irradiated with the laser beam 220.

In this preferred embodiment, the thickness d3 of the gate insulating film 208 is set to be 105 nm, which makes the gate insulating film 208 function as an antireflective film most effectively with respect to the wavelength of 308 nm of the laser beam. That is why the effective energy of the laser beam 220 to be absorbed into the TFT's semiconductor layer 206 increases compared to a situation where the semiconductor layer 206 is directly irradiated with the laser beam 220 with no silicon dioxide film (i.e., the gate insulating film 208 in this case) interposed between them. As a result, the radiation energy of the laser beam 220 can have a lower setting. In this preferred embodiment, the laser beam 220 is supposed to have a radiation energy of 100 to 220 mJ/cm², e.g., 150 mJ/cm². This is less than a half of the energy setting for a situation where there is no silicon dioxide film over the semiconductor layer 206, e.g., the crystallization process step using a laser beam as already described with reference to FIG. 4(B).

As a result, the source/drain regions 213 of the TFT's semiconductor layer 206 not only get re-crystallized but also are activated with P atoms introduced into the Si lattice and have their resistance reduced. Consequently, their sheet resistance decreases to approximately 200 to 400 Ω/□. In this activation process step, the channel region 215 is overlapped by, and shielded with, the gate electrode 209, and therefore, is not irradiated with the laser beam 220. For that reason, the channel region 215 is never affected by this process step and can maintain its crystal state as it is.

On the other hand, the TFD's semiconductor layer 210 is also irradiated with the laser beam 220 but is not covered with any film that functions as an antireflective film, thus reducing the effective radiation energy to a low level. On top of that, the semiconductor layer 210 is as thick as 400 nm, and therefore, has a great heat capacity. Consequently, the semiconductor layer 210 is not affected so much by the laser beam 220 radiated. As a result, desorption of hydrogen atoms can be minimized and a good hydrogenated amorphous semiconductor state can be maintained.

After that, as shown in FIG. 4(H), either a silicon dioxide film or a silicon nitride film is deposited as an interlevel dielectric film. In this preferred embodiment, an interlevel dielectric film consisting of a silicon nitride film 221 and a silicon dioxide film 222 is formed. Then, contact holes are cut through the silicon nitride film 221 and silicon dioxide film 222 and a metallic material is deposited thereon and patterned into electrodes and interconnects 223 and 224 to form parts of a TFT and a TFD. In this manner, a thin-film transistor 225 and a thin-film diode 226 are completed. Optionally, to protect these components, a passivation film of silicon nitride, for example, may be deposited over the thin-film transistor 225 and the thin-film diode 226.

According to this method, the respective semiconductor layers of a TFT and a TFD (more particularly, the TFT's channel region and the photosensor TFD's intrinsic region) can be formed to have ideal shapes and properties. As a result, the TFT and photosensor TFD can achieve their best performances just as expected. In addition, since the TFT's semiconductor layer and the TFD's opaque layer are formed according to this preferred embodiment by patterning the same semiconductor film, the manufacturing process can be simplified and its cost can be reduced as well.

### Embodiment 3

Hereinafter, a third preferred embodiment of a semiconductor device according to the present invention will be described. This third preferred embodiment will be described in further detail as being applied to a process for fabricating a pixel TFT and its storage capacitor for use as a unit of display, a TFT circuit with a CMOS configuration for use as a driver, and a photosensor TFD at the same time on a glass substrate. The semiconductor device of this preferred embodiment can be used as an active-matrix-addressed liquid crystal display device including a built-in photosensor or an organic EL display device, for example.

FIGS. 5 to 7 are cross-sectional views illustrating the respective process steps to fabricate an n-channel thin-film transistor 329 and a p-channel thin-film transistor 330 to form a driver circuit, an n-channel thin-film transistor 331 to drive a pixel electrode, a storage capacitor 332 connected to the n-channel transistor 331, and a thin-film diode 333 as a photosensor. These process steps are carried out in the same order that these drawings (i.e., from FIG. 5(A) through 7(K)) are arranged.

First, as shown in FIG. 5(A), an opaque layer 302 is formed on the surface of a glass substrate 301, on which a TFT and a TFD will be fabricated, in order to shield the TFD from the light coming from under the back surface of the substrate. The opaque layer 302 may be either a metal film or a silicon film. In this preferred embodiment, a molybdenum (Mo) film is deposited by sputtering process and then patterned, thereby forming the opaque layer 302. The opaque layer 302 may have a thickness of 30 nm to 300 nm (preferably in the range of 50 nm to 200 nm) and has a thickness of 100 nm in this preferred embodiment.

Next, as shown in FIG. 5(B), undercoat films 303 and 304 of silicon dioxide, silicon nitride or silicon oxynitride, for example, and an amorphous semiconductor film 305 are deposited in this order by plasma CVD process, for example, on the glass substrate 301 and on the opaque layer 302.

The undercoat films 303 and 304 are provided to prevent impurities from diffusing from the glass substrate. In this preferred embodiment, a silicon nitride film is deposited to a thickness of approximately 100 nm as the lower, first undercoat film 303, and then a silicon dioxide film is deposited as the second undercoat film 304 to a thickness of approximately 200 nm.

As the amorphous semiconductor film 305, an intrinsic (I-type) amorphous silicon film (a-Si film) may be deposited to a thickness of approximately 20-80 nm (e.g., 40 nm) by plasma CVD process, for example. Thereafter, the a-Si film 305 may be heated and dehydrated, if necessary. For example, the a-Si film 305 may be heated to a temperature of 400° C. to 550° C. for several ten minutes to several hours within an inert atmosphere (such as nitrogen gas ambient). This heat treatment is preferably carried out because if the concentration of hydrogen in the a-Si film 305 were too high, hydrogen atoms could suddenly pop out of the film and would cause ablation when the a-Si film is irradiated with a laser beam to get crystallized.

Subsequently, as shown in FIG. 5(C), the a-Si film 305 is irradiated with a laser beam 306 that has come from over the substrate 301. The a-Si film 305 is melted when irradiated with the laser beam 306 but soon gets solidified and crystallized to turn into a crystalline silicon film 305c eventually.

In this process step, an XeCl excimer laser beam (with a wavelength of 308 nm) or a KrF excimer laser beam (with a wavelength of 248 nm) may be used as the laser beam 306. Also, in this process step, the sizes of the laser beam spot 306 are determined so that an elongated beam spot is formed on the surface of the substrate 301. And by sequentially scanning the surface of the substrate 301 perpendicularly to the direction in which the beam spot is elongated, the amorphous silicon film gets crystallized over the entire surface of the substrate. In this case, if the surface is scanned so that the beam spots partially overlap with each other, an arbitrary point on the amorphous silicon film 305 will be irradiated with the laser beam a number of times, thus contributing to increasing the uniformity of crystallinity. In this preferred embodiment, the sizes of the beam spot are determined so that the beam spot has an elongated shape of 300 mm×0.4 mm on the surface of the substrate 301 and the substrate is sequentially scanned at a step of 0.02 mm perpendicularly to the direction in which the beam spot is elongated. That is to say, any arbitrary point on the silicon film gets irradiated with the laser beam 20 times in total. Examples of laser beams that can be used in this process step include KrF and XeCl excimer laser beams of pulsed or continuous wave type described above but also a YAG laser beam or a YVO₄ laser beam as well.

Thereafter, excessive portions of the crystalline silicon film 305c are removed, thereby electrically isolating these two element regions from each other. As a result, as shown in FIG. 5(D), formed are semiconductor islands 307n and 307p to be the respective active regions (including source/drain regions and channel regions) of n-channel and p-channel TFTs that will form a driver circuit later and a semiconductor island 307g to be the active region (including source/drain regions and a channel region) of an n-channel TFT for driving a pixel electrode and to be the lower electrode of a storage capacitor that is connected to the n-channel TFT.

Optionally, some or all of these semiconductor layers may be doped with boron (B) as a p-type dopant in a concentration of approximately 1×10¹⁶/cm³ to 5×10¹⁷/cm³ to control the threshold voltage. Boron (B) may be introduced either when the ion doping process is performed or when an amorphous silicon film is deposited.

Next, as shown in FIG. 5(E), a gate insulating film 308 is deposited to cover the semiconductor layers 307n, 307p and 307g and then photoresist masks 309n, 309p and 309g are formed. Then, using these photoresist masks 309n, 309p and 309g as masks, the semiconductor islands 307n and 307g are lightly implanted with dopant (phosphorus) ions 310.

In this preferred embodiment, a silicon dioxide film is deposited to a thickness of 20 nm to 150 nm (e.g., 70 nm in this preferred embodiment) as the gate insulating film 308. To make the silicon dioxide film, in this preferred embodiment, TEOS (tetraethoxy orthosilicate) is used as a source material and decomposed and deposited with oxygen by performing an RF plasma CVD process with the substrate heated to a temperature of 150° C. to 600° C. (preferably at a temperature of 300° C. to 450° C.). Alternatively, also using TEOS as a source material and ozone gas, the silicon dioxide film may also be deposited by performing either a low pressure CVD process or an ordinary pressure CVD process with the substrate heated to a temperature of 350° C. to 600° C. (preferably a temperature of 400° C. to 550° C.). Optionally, after the silicon dioxide film has been deposited, the substrate may also be annealed for one to four hours at a temperature of 500° C. to 600° C. within an inert gas atmosphere in order to improve the bulk property of the gate insulating film 308 itself or the property of the interface between the crystalline silicon film and the gate insulating film. Still alternatively, any other insulating film with silicon, having either a single layer structure or a multilayer structure, may also be used as the gate insulating film 308.

The photoresist masks 309n, 309p and 309g are arranged over the semiconductor islands 307n, 307p, and 307g, respectively. Specifically, the semiconductor layer 307n to be the active region of an n-channel TFT has both ends thereof (to be source and channel regions later) exposed with only its center portion (to be the channel region) masked with the photoresist mask 309n. The semiconductor layer 307g to be the active region of a pixel TFT and the lower electrode of a storage capacitor has its portion to be the active region of the pixel TFT masked with the photoresist mask 309g but has its portion to be the lower electrode of the storage capacitor exposed. On the other hand, the semiconductor layer 307p to be the active region of a p-channel TFT is entirely covered with the photoresist mask 309p.

The dopant (phosphorus) ions 310 may be introduced by performing an ion doping process. Specifically, phosphine (PH₃) is used as a doping gas, the accelerating voltage is defined within the range of 60 kV to 90 kV (e.g., 70 kV), and the dose is defined within the range of 5×10¹² cm⁻² to 5×10¹⁴ cm⁻² (e.g., 5×10¹³ cm⁻²). As a result of this process step, those exposed portions of the semiconductor islands 307n and 307g that are not covered with the photoresist masks 309n and 309g are lightly doped with phosphorus ions 313 and turn into n-type light doped regions 311n and 311g, respectively. On the other hand, the phosphorus ions 310 are not implanted into the regions covered with the photoresist masks 309n and 309g. Likewise, the semiconductor island 307p is entirely masked with the photoresist mask 309p, and therefore, are not doped with phosphorus ions 310 at all, either.

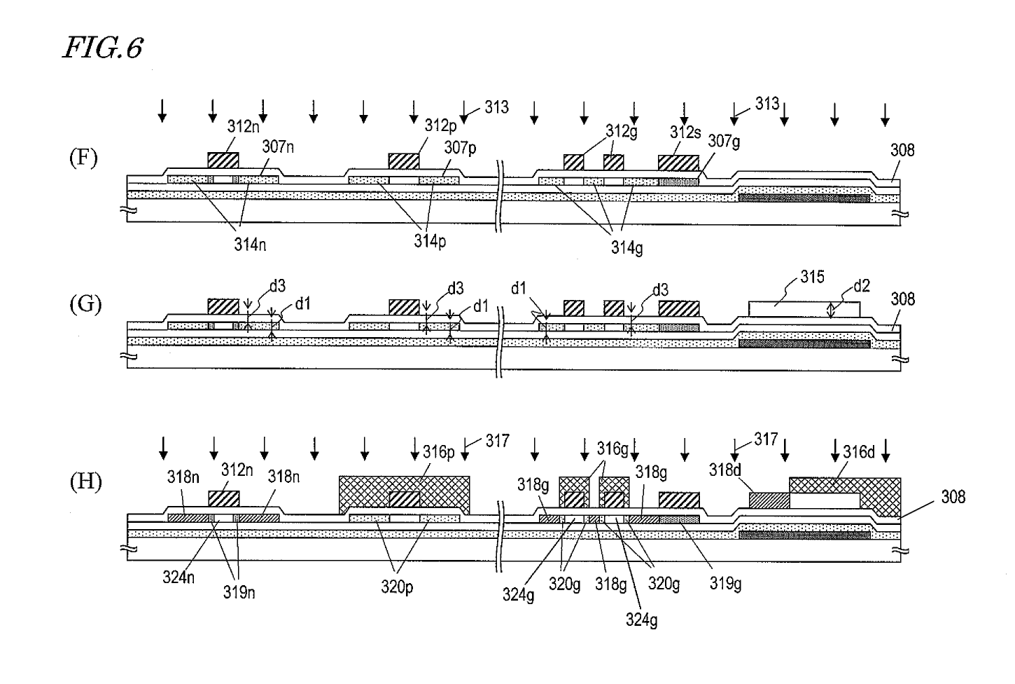

Next, as shown in FIG. 6(F), gate electrodes 312n, 312p and 312g are formed on the semiconductor islands 307n, 307p and 307g, respectively, and the upper electrode 312s of a storage capacitor is formed on the semiconductor island 307g. In such a state, using the gate electrodes 312n, 312p and 312g and the upper electrode 312s of the storage capacitor as masks, the active regions of the respective TFTs are lightly doped with dopant (phosphorus) ions 313 again by performing an ion doping process.

In this process step, the gate electrode 312g that will form part of a pixel TFT later has a so-called “dual-gate structure” in which two split TFTs are directly connected together in order to reduce the amount of leakage current to flow when the pixel TFT is in OFF state. Alternatively, the pixel TFT may have an even greater number of gate electrodes 312g (or a greater number of TFTs connected in series together), which form either a triple gate structure or a quad-gate structure.

The gate electrodes 312n, 312p and 312g and the upper electrode 312s of the storage capacitor are formed by depositing a metal film by sputtering process and then patterning it. The metal film may be made of Al, Mo, Ta, W Ti, or an alloy including any of these elements as a main ingredient. The usable material is limited by the condition on which a heat treatment should be carried out later. Examples of alternative materials include tungsten silicide, titanium silicide and molybdenum silicide. In this preferred embodiment, an Al—Ti alloy film with a thickness of 300 to 600 nm (e.g., 450 nm), which includes 0.2% to 3% of Ti, is used.

In the process step of implanting the phosphorus ions 313, phosphine (PH₃) is used as a doping gas, the accelerating voltage is defined within the range of 60 kV to 90 kV (e.g., 70 kV), and the dose is defined within the range of 1×10¹² cm⁻² m to 1×10¹⁴ cm⁻² (e.g., 2×10¹³ cm⁻²). As a result of this process step, those portions of the semiconductor islands 307n, 307p and 307g that are not covered with the gate electrodes 312n, 312p and 312g or the upper electrode 312s of the storage capacitor are lightly doped with phosphorus ions 313 for the second time and turn into n-type light doped regions 314n, 314p and 314g, respectively. On the other hand, the phosphorus ions 313 are not implanted at all into the regions covered with the gate electrodes 312n, 312p and 312g and the upper electrode 312s of the storage capacitor.

Next, as shown in FIG. 6(G), a semiconductor island 315 to be the TFD's active region (including n-type and p-type regions and an intrinsic region) is formed by depositing a second amorphous silicon film on the gate insulating film 308 and then patterning it. The semiconductor island 315 may be formed by performing a plasma CVD process with SiH₄ supplied as a source gas and with the substrate heated to a temperature of 250° C. to 400° C. According to such a method, a hydrogenated amorphous silicon film of quality, in which the dangling bonds of Si atoms have been terminated with hydrogen atoms, can be obtained.

In this process step, the thickness d2 of the semiconductor island 315 is preferably set to be greater than the thickness d1 of the semiconductor layers 307n, 307p and 307g to be the TFT's active region (which may be 40 nm in this preferred embodiment). Also, although the thickness of the gate insulating film 308 is set to be 70 nm according to this preferred embodiment, the exposed portions of the gate insulating film that are not masked with the gate electrodes had their thickness reduced by about 15 nm when subjected to over-etching because the gate electrodes 312n, 312p and 312g have been formed by dry etching. As a result, those exposed portions of the gate insulating film 308 that are not masked with the gate electrodes now have a thickness d3 of 55 nm. More particularly, the thickness d2 of the semiconductor island 315 is preferably defined to be greater than the sum of the thickness d3 of the gate insulating film 308 (which may be 55 nm in this example) and the thickness d1 of the semiconductor layers 307n, 307p and 307g (which may be 95 nm in this example). Consequently, according to this preferred embodiment, the thickness d2 of the semiconductor island 315 is preferably more than 95 nm, and may be 300 nm, for example.

Next, a doping mask 316g of photoresist is formed in a size that is big enough to easily cover the portion to be a pixel TFT's gate electrode 312p with some margin left as shown in FIG. 6(H). In addition, another doping mask 316p of photoresist is also formed so as to easily cover the semiconductor layer 307p entirely as for a portion to be a p-channel TFT later. Furthermore, still another doping mask 316d of photoresist is formed so as to partially expose the semiconductor layer 315 as for a portion to be a photosensor's TFD. Thereafter, the respective semiconductor layers are implanted with dopant (phosphorus) ions 317 heavily by performing an ion doping process using that portion to be the n-channel TFT's gate electrode 312n, that portion to be the storage capacitor's upper electrode 312s, and the photoresist masks 316p, 316g and 316d as masks. In this process step, phosphine (PH₃) is used as a doping gas, the accelerating voltage is defined within the range of 60 kV to 90 kV (e.g., 70 kV), and the dose is defined to fall within the range of 1×10¹⁵ cm⁻² to 1×10¹⁶ cm⁻² (e.g., 5×10¹⁵ cm²).

As a result of this process step, in the semiconductor layer 307n to form part of an n-channel TFT, the exposed portions that are not covered with the gate electrode 312n to be are heavily doped with dopant (phosphorus) atoms 317, thereby defining regions to be n-channel TFT's source/drain regions 318n that are self-aligned with the gate electrode 312n to be. On the other hand, other portions of the same semiconductor layer 307n, which have been covered with the gate electrode 312n to be and have not been heavily doped with phosphorus atoms 317 but which were lightly doped with phosphorus atoms in the previous process step, will be so-called “GOLD (gate overlapped lightly doped drain)” regions 319n overlapped with the gate electrode 312n. Meanwhile, still another portion of the semiconductor layer 307n that is located under the gate electrode 312n to be and that has not been lightly doped with phosphorus atoms, either, will be a channel region 324n. These LDD regions can not only reduce the overconcentration of an electric field in the junctions between the channel region and the source/drain regions but also minimize deterioration to be caused by hot carriers. As a result, the reliability of an n-channel TFT in the driver circuit can be increased significantly.

The same can be said about the pixel TFT. That is to say, in the semiconductor layer 307g, exposed portions that are not covered with the photoresist mask 316g are heavily doped with dopant (phosphorus) atoms 317, thereby defining regions to be pixel TFT's (i.e., n-channel TFT's) source/drain regions 318g. On the other hand, other portions of the same semiconductor layer 307g, which have been covered with the photoresist mask 316g and have not been heavily doped with phosphorus atoms 317 but which were lightly doped with phosphorus atoms in the previous process step, will be LDD regions 320g. Meanwhile, still another portion of the semiconductor layer 307g that is located under the gate electrode 312g to be and that has not been lightly doped with phosphorus atoms, either, will be a channel region 324g. By forming such an LDD structure that has been offset outward under the gate electrode, the amount of leakage current to flow through the TFT in OFF state can be reduced significantly. In the semiconductor layer 307p to form part of a p-channel TFT, its portion covered with the photoresist mask 316p is not heavily doped with the n-type dopant 317. Likewise, in the semiconductor layer 315 to form part of a photosensor TFD, portions that are not covered with the photoresist mask 316d are heavily doped with dopant (phosphorus) atoms 317, thereby defining n-type heavily doped regions 318d.

In this process step, the in-film concentration of the n-type dopant element (phosphorus) 310 in the GOLD region 319n of the n-channel TFT is preferably in the range of 5×10¹⁷/cm³ to 1×10¹⁹/cm³. And in the LDD region 320g of the pixel TFT, the in-film concentration of the n-type dopant element (phosphorus) 313 is preferably in the range of 1×10¹⁷/cm³ to 5×10¹⁸/cm³. In other words, if the dopant concentrations fall within these ranges, those regions 319n and 320g will function effectively as either GOLD or LDD regions.

This process step of heavily doping the semiconductor layers with phosphorus element 317 is carried out so that the phosphorus ions 317 pass through the gate insulating film 308 to reach the semiconductor islands 307n and 307g to form respective parts of an n-channel TFT and a pixel TFT but that the semiconductor island 315 to be the active region of a TFD is laid bare (i.e., exposed) to the phosphorus ions 317. In this process step, the thickness d1 of the semiconductor layers 307n and 307g, the thickness d2 of the semiconductor layer 315 and the thickness d3 of the exposed portions of the gate insulating film 308 that are not masked with the gate electrode also satisfy d1+d3<d2. That is why the semiconductor islands (i.e., crystalline semiconductor layers) 307n and 307g to be the TFT's active region can be doped deep enough to reduce the resistance in the source/drain regions. On the other hand, the hydrogenated amorphous semiconductor layer 315 to be the TFD's active region has a lighter doping damage because the dopant is not implanted so deep for its thickness. Furthermore, the semiconductor layer 315 is thick enough to have a great heat capacity. As a result, the implantation damage and desorption of hydrogen atoms due to a rise in temperature during the implantation process can be both minimized.

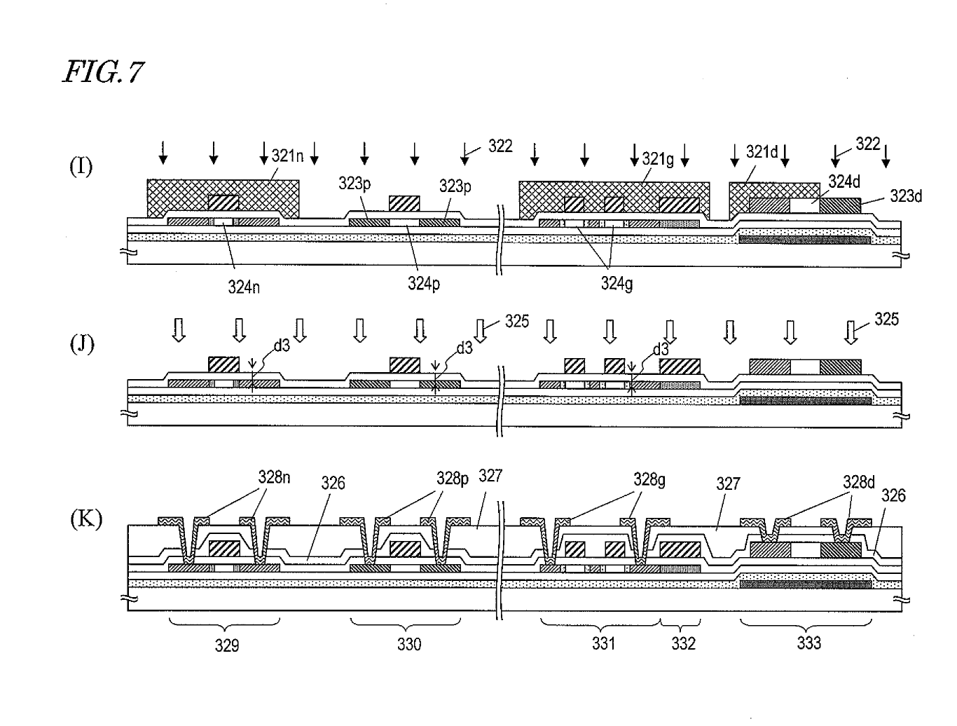

Next, after the photoresist masks 316p, 316g and 316d have been removed, doping masks 321n, 321g and 321d of photoresist are formed again to cover entirely the semiconductor layer 307n to form part of the n-channel TFT and the semiconductor layer 307g to form part of the pixel TFT and its storage capacitor and to cover partially the semiconductor layer 315 to form part of the TFD as shown in FIG. 7(I). And the semiconductor layers 310p and 310d to form respective parts of the p-channel TFT and the TFD are implanted with dopant (boron) ions 322 to make them p-type by performing an ion doping process using the photoresist masks 321n, 321g and 321d and the portion to be the p-channel TFT's gate electrode 312p as masks. In this process step, diborane (B₂H₆) is used as a doping gas, the accelerating voltage is defined within the range of 40 kV to 90 kV (e.g., 75 kV), and the dose is defined to fall within the range of 1×10¹⁵ cm⁻² to 1×10¹⁶ cm² (e.g., 3×10¹⁵ cm⁻²).

As a result of this process step, the semiconductor layer 307p to form part of the p-channel TFT is heavily doped with boron atoms 322 in the regions that are not masked with the gate electrode-to-be 312p. Also, as a result of this process step, the n-type dopant (phosphorus) 313 that has been introduced lightly in the previous process step into the region 320p has its conductivity type inverted into p-type, thereby turning the region 320p into TFT's source/drain regions 323p, which are self-aligned with the gate electrode 312p. Meanwhile, the region under the gate electrode-to-be 312p is not heavily doped with boron but will be channel region 324p.

Furthermore, as for the semiconductor layer 315 to form part of a photosensor TFD, the region not covered with the photoresist mask 321d is heavily doped with boron 322 to turn into a p-type region 323d to form part of the TFD. On the other hand, the region that has been masked with the photoresist mask 321d and then the photoresist mask 316d in the previous process step and that has been heavily doped with neither phosphorus nor boron will be the TFD's intrinsic region 324d. In this process step, the semiconductor layer 307n to be an n-channel TFT and the semiconductor layer 307g to be a pixel TFT and the lower electrode of its storage capacitor are entirely covered with the masks 321n and 321g and are not doped with boron 322 at all.

This process step of heavily doping the semiconductor layers with boron element 322 is carried out so that the boron ions 322 pass through the gate insulating film 308 to reach the semiconductor island 307p to form part of a p-channel TFT but that the semiconductor island 315 to be the active region of a TFD is laid bare (i.e., exposed) to the boron ions 322. In this process step, the thickness d1 of the semiconductor layers 307p, the thickness d2 of the semiconductor layer 315 and the thickness d3 of the exposed portions of the gate insulating film 308 that are not masked with the gate electrode also satisfy d1+d3<d2. That is why the semiconductor island (i.e., crystalline semiconductor layer) 307p to be the TFT's active region can be doped deep enough to reduce the resistance in the source/drain regions. On the other hand, the hydrogenated amorphous semiconductor layer 315 to be the TFD's active region has a lighter doping damage because the dopant is not implanted so deep for its thickness. Furthermore, the semiconductor layer 315 is thick enough to have a great heat capacity. As a result, the implantation damage and desorption of hydrogen atoms due to a rise in temperature during the implantation process can be both minimized.

Thereafter, the photoresist masks 321n, 321g and 321d are removed and then these layers are irradiated with a laser beam 325 that has come from over the substrate 301 as shown in FIG. 7(J). The laser beam 325 may be radiated as in the crystallization process step described above. An XeCl excimer laser beam (with a wavelength of 308 nm) may be used as the laser beam 325. Also, in this process step, the sizes of the laser beam spot 325 are determined so that an elongated beam spot is formed on the surface of the substrate 301. And by sequentially scanning the surface of the substrate 301 perpendicularly to the direction in which the beam spot is elongated, the entire surface of the substrate can be irradiated. In this case, if the surface is scanned so that the beam spots partially overlap with each other, an arbitrary point on the substrate will be irradiated with the laser beam a number of times, thus contributing to increasing the uniformity of crystallinity.

In this process step, by radiating a laser beam 325 toward the n-channel TFT's, p-channel TFT's and pixel TFT's semiconductor layers 307n, 307p and 307g from over them, their exposed portions that are not masked with the gate electrodes 312n, 312p and 312g to be, i.e., the regions to be source/drain regions 318n, 323p and 318g and pixel TFT's LDD regions 320g, are irradiated with the laser beam 325 that has passed through the gate insulating film 308 with the thickness d3. As a result, the TFD's semiconductor layer 315 is directly irradiated with the laser beam 325.

In this preferred embodiment, the thickness d3 of the exposed portion of the gate insulating film 308 is set to be 55 nm, which makes the gate insulating film 308 function as an antireflective film most effectively with respect to the wavelength of 308 nm of the laser beam. That is why the effective energy of the laser beam 325 to be absorbed into the TFT's semiconductor layer 307 increases compared to a situation where the semiconductor layer 307 is directly irradiated with the laser beam 325 with no silicon dioxide film (i.e., the gate insulating film 308 in this case) interposed between them. As a result, the radiation energy of the laser beam 325 can have a lower setting. In this preferred embodiment, the laser beam 325 is supposed to have a radiation energy of 100 to 220 mJ/cm², e.g., 140 mJ/cm². This is less than a half of the energy setting for a situation where there is no silicon dioxide film over the semiconductor layer 307n, 307p or 307g, e.g., the crystallization process step using a laser beam as already described with reference to FIG. 5(C).

As a result, the respective source/drain regions of the TFTs' semiconductor layers 307n, 307p and 307g not only get re-crystallized but also are activated with P or B atoms introduced into the Si lattice and have their resistance reduced. Consequently, the sheet resistance in the source/drain regions 318n and 318g of the n-channel TFT and the pixel TFT decreases to approximately 200 to 400Ω/□. On the other hand, the sheet resistance in the source/drain regions 323p of the p-channel TFT decreases to approximately 300 to 500Ω/□. In this activation process step, the respective channel regions 324n, 324p and 324g of the TFTs are overlapped by, and shielded from incoming light by, the gate electrodes 312n, 312p and 312g to be, and therefore, are not irradiated with the laser beam 325. For that reason, these channel regions 324n, 324p and 324g are never affected by this process step and can maintain their crystal state as it is.

On the other hand, the TFD's semiconductor layer 315 is also irradiated with the laser beam 325 but is not covered with any silicon dioxide film that functions as an antireflective film, thus reducing the effective radiation energy to a low level. On top of that, the semiconductor layer 325 is as thick as 300 nm, and therefore, has increased heat capacity. Consequently, the semiconductor layer 315 is not affected so much by the laser beam 325 radiated. As a result, desorption of hydrogen atoms can be minimized and a good hydrogenated amorphous semiconductor state can be maintained.

After that, as shown in FIG. 7(K), a silicon nitride film, a silicon dioxide film or a silicon oxynitride film is deposited as an interlevel dielectric film to a thickness of 400 nm to 1,500 nm (typically in the range of 600 nm to 1,000 nm), for example. In this preferred embodiment, an interlevel dielectric film consisting of a silicon nitride film 326 with a thickness of 200 nm and a silicon dioxide film 327 with a thickness of 700 nm is formed. The silicon nitride film 326 may be formed by performing a plasma CVD process using SiH₄ and NH₃ as source gases. The silicon dioxide film 327 may be formed by performing a plasma CVD process using TEOS and O₂ as source gases. It is preferred that the silicon nitride film 326 and the silicon dioxide film 327 be formed continuously. However, the interlevel dielectric film does not always have to be made of these materials or formed in this manner. Alternatively, any other insulating films with silicon may also be used. Furthermore, the interlevel dielectric film may have either a single-layer structure or a multilayer structure. In the latter case, an organic insulating layer of an acrylic material, for example, may be provided as the upper insulating film.

Thereafter, a heat treatment process is carried out at a temperature of 300° C. to 500° C. for 30 minutes to several hours to hydrogenate the semiconductor layers. This is a process step for terminating and inactivating dangling bonds, which would deteriorate the performance of a TFT, by supplying hydrogen atoms to the interface between the active regions and the gate insulating film. In this preferred embodiment, the heat treatment was conducted at 400° C. for an hour within a nitrogen gas ambient including approximately 3% of hydrogen. If the interlevel dielectric film (e.g., the silicon nitride film 326, in particular) includes sufficient hydrogen, then even a heat treatment within the nitrogen gas ambient will also be effective enough. Alternatively, the semiconductor layers may also be hydrogenated by plasma hydrogenation process (that uses hydrogen excited by plasma).

Next, contact holes are cut through the interlevel dielectric films 326, 327 and metallic materials (such as a stack of titanium nitride and aluminum) are deposited and patterned into electrodes and interconnects 328n, 328p, 328g and 328d for TFTs. The titanium nitride film is provided as a barrier film that prevents aluminum from diffusing and entering the semiconductor layers. In this manner, an n-channel thin-film transistor 329 and a p-channel thin-film transistor 330 to make a driver, a pixel switching thin-film transistor 331, a storage capacitor 332 connected to the transistor 331, and a photosensor thin-film diode 333 are completed as shown in FIG. 7(K).

Although not shown, a transparent conductor film of ITO, for example, is connected to one of the two pairs of electrodes and interconnects 328g of the pixel switching thin-film transistor 331 to form a pixel electrode. If necessary, contact holes may also be cut over the gate electrodes 312n and 312p and the electrodes may be connected together with the interconnects 328 as needed. Optionally, to protect the TFTs, a passivation film of silicon nitride may also be deposited over those TFTs.

The TFTs fabricated by the process of the preferred embodiment described above had very good performances. Specifically, the n-channel thin-film transistor 329 had as high a field effect mobility as 80 cm²/Vs to 150 cm²/Vs with a threshold voltage of approximately 1.5 V, while the p-channel thin-film transistor 330 had as high a field effect mobility as 50 cm²/Vs to 100 cm²/Vs with a threshold voltage of approximately −1.5 V. Also, when a circuit such as an inverter chain or a ring oscillator was formed of CMOS circuit elements in which the n- and p-channel thin-film transistors 329 and 330 of the preferred embodiment described above were arranged complementarily, the circuit achieved a higher degree of reliability and more stabilized circuit characteristics. Meanwhile, in the thin-film diode 333, the brightness to darkness ratio as a photosensor unit could be increased significantly, compared to a situation where the TFD and a TFT were made of the same semiconductor layer as in the conventional process. The present inventors confirmed that by forming those different types of semiconductor layers for respective elements independently of each other, the respective device performances could be optimized.

Also, as described above, this preferred embodiment is effectively applicable to an organic EL display device, not just a liquid crystal display device. For example, if a transparent electrode layer, a light emitting layer and an upper electrode layer are deposited in this order over the substrate on which a thin-film transistor and a thin-film diode have been formed by the method described above, a bottom-emission type organic EL display device can be fabricated. Alternatively, a top-emission type organic EL display device may also be fabricated by forming a transparent electrode as the upper electrode layer. In that case, the substrate does not have to be light transmissive.

### Embodiment 4

Hereinafter, a display device with a sensor function will be described as a fourth specific preferred embodiment of the present invention. Such a display device is fabricated by using semiconductor devices according to any of the preferred embodiments of the present invention described above.

A display device with a sensor function according to this preferred embodiment may be a liquid crystal display device with a touchscreen sensor, which includes a display area and a frame area surrounding the display area. The display area includes a plurality of display units (i.e., pixels) and a plurality of photosensor units. Each display unit includes a pixel electrode and a pixel switching TFT. Each photosensor unit includes a TFD. The frame area has a display driver to drive the respective display units, and driver TFTs are used to form the driver. The pixel switching TFTs, the driver TFTs and the photosensor unit TFDs have been integrated together on the same substrate by the method of any of the first through third preferred embodiments of the present invention described above. It should be noted that among those TFTs for use in the display device of the present invention, at least the pixel switching TFTs and the photosensor unit TFDs should be formed on the same substrate by the method described above. Thus, the driver, for example, may be arranged on another substrate.

According to this preferred embodiment, each photosensor unit is arranged adjacent to its associated display unit (e.g., a pixel representing a primary color). In this case, either a single photosensor unit or multiple photosensor units may be provided for a single display unit. Alternatively, one photosensor unit may be provided for a set of multiple display units. For example, one photosensor unit may be provided for a set of three color display pixels, which may be pixels representing the three primary colors of R, G and B. In this manner, the number (or the density) of photosensor units with respect to that of display units may be appropriately selected according to the resolution.

If color filters were arranged closer to the viewer than the photosensor units are, then the sensitivity of the TFDs that form the photosensor units might decrease. That is why it is preferred that no color filters be arranged closer to the viewer than the photosensor units are.

It should be noted that the display device of this preferred embodiment does not have to have the configuration described above. For example, if the photosensor TFDs are arranged in the frame area, the display device can also function as an ambient light sensor that can control the screen brightness according to the illuminance of the external light. Alternatively, if color filters are arranged closer to the viewer than the photosensor units are so that the incoming light is transmitted through the color filters and then received at the photosensor units, the photosensor units can function as a color image sensor.

Hereinafter, a display device according to this preferred embodiment will be described with reference to the accompanying drawings as being applied to a touchscreen panel LCD with a touchscreen panel sensor.

FIG. 9 is a circuit diagram illustrating a configuration for a photosensor unit to be arranged in the display area. The photosensor unit includes a photosensor thin-film diode 601, a signal storage capacitor 602, and a thin-film transistor 603 for retrieving the signal stored in the capacitor 602. After an RST signal has been received and after an RST potential has been written at a node 604, the potential at the node 640 decreases due to the leakage current produced by the incoming light. Then, the gate potential of the thin-film transistor 603 varies to open or close the TFT gate. In this manner, a signal VDD can be retrieved.

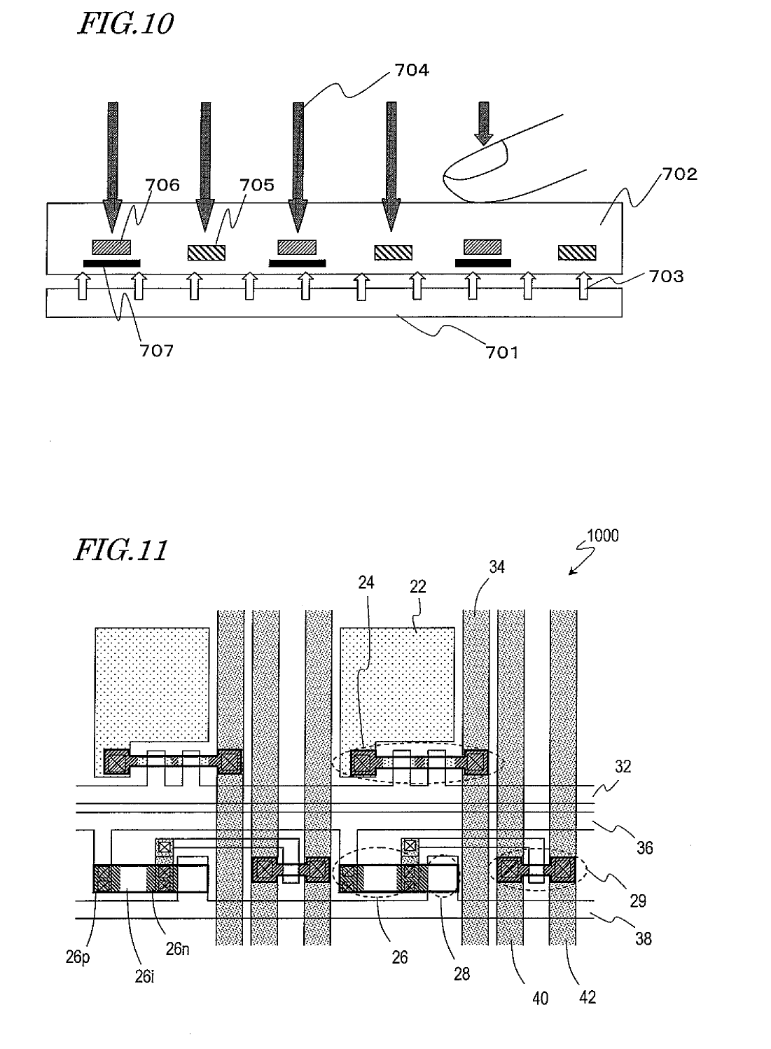

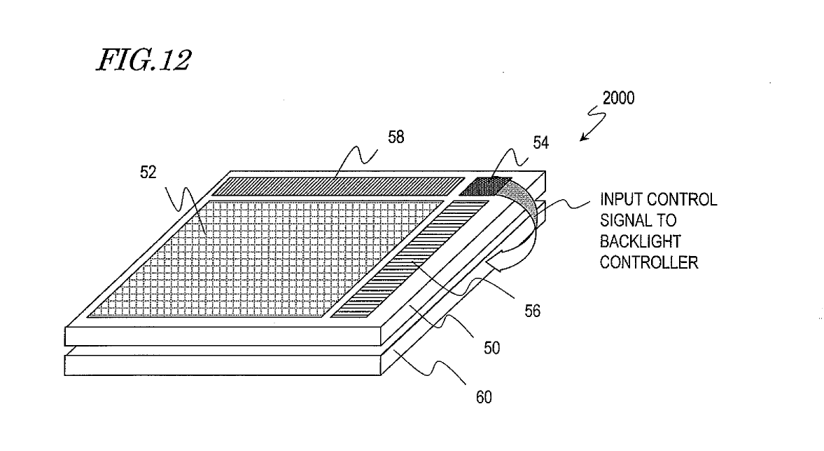

FIG. 10 is a schematic cross-sectional view illustrating an example of an active-matrix-addressed touchscreen panel LCD. In this example, an optical touchscreen sensor section including a photosensor unit is provided for each pixel.

The LCD shown in FIG. 10 includes a liquid crystal module 702 and a backlight 701, which is arranged behind the liquid crystal module 702. Although not shown in FIG. 10, the liquid crystal module 702 includes a light transmissive rear substrate, a front substrate that is arranged to face the rear substrate, and a liquid crystal layer interposed between those two substrates. The liquid crystal module 702 includes a number of display units (i.e., pixels representing the primary colors), each of which includes a pixel electrode (not shown) and a pixel switching thin-film transistor 705 that is connected to the pixel electrode. Also arranged adjacent to each display unit is an optical touchscreen sensor unit including a thin-film diode 706. Although not shown in FIG. 10, either, color filters are arranged closer to the viewer over each display unit but not over any optical touchscreen sensor unit. An opaque layer 707 is arranged between the thin-film diodes 706 and the backlight 701. Thus, the light that has come from the backlight 701 is cut off by the opaque layer 707 and not incident on any thin-film diode 706, which is supposed to be struck by only external light 704. By getting this incoming external light 704 sensed by the thin-film diodes 706, a photosensing type touchscreen panel is realized. It should be noted that the opaque layer 707 has only to be arranged so that the light that has come from the backlight 701 does not enter the intrinsic region of any thin-film diode 706.

FIG. 11 is a schematic plan view illustrating an exemplary rear substrate for use in the active-matrix-addressed touchscreen panel LCD. The LCD of this preferred embodiment is actually made up of a huge number of pixels (including R, G and B pixels). But only two of those pixels are shown in FIG. 11 for the sake of simplicity.

The rear substrate 1000 includes a number of display units (i.e., pixels), each including a pixel electrode 22 and a pixel switching thin-film transistor 24, and a number of optical touchscreen sensor units, each of which is arranged adjacent to an associated one of the display units and which includes a photosensor photodiode 26, a signal storage capacitor 28, and a photosensor follower thin-film transistor 29.

The thin-film transistor 24 may have the same structure as the TFT that has already been described for the third preferred embodiment, i.e., a dual-gate LDD structure including two gate electrodes and an LDD region. The thin-film transistor 24 has its source region connected to a pixel source bus line 34 and has its drain region connected to the pixel electrode 22. The thin-film transistor 24 is turned ON and OFF in response to a signal supplied through a pixel gate bus line 32. With such an arrangement, the pixel electrode 22 and a counter electrode on the front substrate that is arranged to face the rear substrate 1000 apply a voltage to the liquid crystal layer, thereby varying the orientation state of the liquid crystal layer and getting a display operation done.

On the other hand, the photosensor photodiode 26 may have the same configuration as the TFD that has already been described for the third preferred embodiment, and has a p⁺-type region 26p, an n⁺-type region 26n and an intrinsic region 26i arranged between these two regions 26p and 26n. The signal storage capacitor 28 uses a gate electrode layer and an Si layer as electrodes, and forms capacitance in its gate insulating film. The photosensor photodiode 26 has its p⁺-type region 26p connected to a photosensor RST signal line and has its n⁺-type region 26n connected to the lower electrode (Si layer) of the signal storage capacitor 28 and to a photosensor RWS signal line 38 by way of the capacitor 28. The n⁺-type region 26n is further connected to the gate electrode layer of the photosensor follower thin-film transistor 29, of which the source and drain regions are connected to a photosensor VDD signal line 40 and a photosensor COL signal line 42, respectively.

As described above, the photosensor photodiode 26, the signal storage capacitor 28, and the photosensor follower thin-film transistor 29 respectively correspond to the thin-film diode 601, capacitor 602 and thin-film transistor 603 of the driver shown in FIG. 10 and together form a photosensor driver. Hereinafter, it will be described how this driver performs a photosensing operation.

(1) First of all, through the RWS signal line 38, a RWS signal is written on the signal storage capacitor 28. As a result, a positive electric field is generated in the n⁺-type region 26n of the photosensor photodiode 26 and a reverse bias will be applied to the photosensor photodiode 26. (2) Next, photo-leakage current is produced in the photosensor photodiodes 26 in a surface region of the substrate that is irradiated with light, thus moving the electrical charges toward the RST signal line 36. (3) As a result, the potential decreases in the n⁺-type region 26n and that potential variation in turn causes a variation in the gate voltage applied to the photosensor follower thin-film transistor 29. (4) A VDD signal is supplied through the VDD signal line 40 to the source electrode of the photosensor follower thin-film transistor 29. When the gate voltage varies as described above, the amount of the current flowing through the COL signal line 42 that is connected to the drain electrode changes. Thus, the electrical signal representing that current can be output through the COL signal line 42. (5) And through the COL signal line 42, an RST signal is written on the photosensor photodiode 26, thereby resetting the potential at the signal storage capacitor 28. By performing this series of processing steps (1) through (5) a number of times while getting scanning done, photosensing can be carried out.

In the touchscreen panel LCD of this preferred embodiment, the rear substrate does not always have to have the configuration shown in FIG. 11. Optionally, a storage capacitor Cs may be provided for each pixel switching TFT, for example. In the example illustrated in FIG. 11, an optical touchscreen sensor unit is arranged adjacent to each of the R, G and B pixels. Alternatively, one optical touchscreen sensor unit may be provided for a set of three color display pixels (i.e., R, G and B pixels) just as described above.

Now take a look at FIG. 10 again. In the example described above, the thin-film diodes 706 are arranged in the display area and used as a touchscreen sensor as can be seen from the cross-sectional view illustrated in FIG. 11. Alternatively, the thin-film diodes 706 may also be arranged outside of the display area and may be used as an ambient light sensor for controlling the luminance of the backlight 701 according to the illuminance of the external light 704.

FIG. 12 is a perspective view illustrating an LCD with an ambient light sensor. The LCD 2000 includes an LCD substrate 50 including a display area 52, a gate driver 56, a source driver 58 and a photosensor section 54, and a backlight 60, which is arranged behind the LCD substrate 50. A portion of the LCD substrate 50, which surrounds the display area 52 and which includes the drivers 56 and 58 and the photosensor section 54, will be referred to herein as a “frame area”.

The luminance of the backlight 60 is controlled by a backlight controller (not shown). Although not shown, the display area 52 and the drivers 56 and 58 use TFTs and the photosensor section 54 uses TFDs. The photosensor section 54 generates an illuminance signal representing the illuminance of the external light and enters it into the backlight controller using connection with a flexible substrate. In response to the illuminance signal, the backlight controller generates a backlight control signal and outputs it to the backlight 60.

Optionally, by applying the present invention, an organic EL display device with an ambient light sensor can also be provided. Such an organic EL display device may also have a configuration including display units and photosensor units on the same substrate just like the LCD shown in FIG. 12 but does not need to have the backlight 60 behind the substrate. In that case, the photosensor section 54 is connected to the source driver 58 with a cable provided for the substrate 50 so that the illuminance signal is supplied from the photosensor section 54 to the source driver 58. In response to that illuminance signal, the source driver 58 adjusts the luminance of the display area 52.

While the present invention has been described with respect to specific preferred embodiments thereof, it will be apparent to those skilled in the art that the disclosed invention may be modified in numerous ways and may assume many embodiments other than those specifically described above as long as those modifications fall within the true spirit and scope of the invention. For example, by using the TFTs of the present invention, analog drivers and digital drivers may be fabricated on a glass substrate at the same time. Such an analog driver may include a source driver, a pixel section and a gate driver. The source driver may include a shift register, a buffer and a sampling circuit (transfer gate). On the other hand, the gate driver may include a shift register, a level shifter and a buffer. Also, if necessary, a level shifter circuit may be provided between the sampling circuit and the shift register. Furthermore, according to the manufacturing process of the present invention, a memory and a microprocessor may also be fabricated.

The present invention provides a semiconductor device including high-performance TFTs and TFDs that have been fabricated on the same substrate using their best semiconductor films. As a result, TFTs with high field effect mobility and ON/OFF ratio, which can be used as driver TFTs and pixel electrode switching TFTs, and TFDs that will have a low dark current value when used as photosensors and a high SNR with respect to the incoming light (i.e., a high bright current to dark current ratio), can be fabricated by performing the same series of manufacturing processing steps. Among these semiconductor layers, if their portions to be the channel region that will have significant influence on the field effect mobility of TFTs and the intrinsic region that will have great impact on the photosensitivity of TFDs are optimized in terms of their thicknesses and crystal states, the respective semiconductor components can achieve their best device performances required. Furthermore, such high-performance semiconductor components are provided by performing a simple manufacturing process, and a product of a smaller size and with improved performance can be provided at a reduced cost.

### INDUSTRIAL APPLICABILITY

The present invention has a broad variety of applications and is applicable to any kind of semiconductor device with TFTs and TFDs and to an electronic device in any field that uses such a semiconductor device. For example, a CMOS circuit and a pixel section fabricated by carrying out the present invention may be used in an active-matrix-addressed liquid crystal display device and an organic EL display device. Such a display device may be used as either the display screen of a cellphone or a portable game console or the monitor of a digital camera. Consequently, the present invention is applicable to any kind of electronic device including a built-in LCD or organic EL display device.

The present invention can be used particularly effectively in a display device such as an active-matrix-addressed LCD or an organic EL display device, an image sensor, a photosensor, and an electronic device including any of these devices in combination. It would be particularly beneficial to apply the present invention to a display device with a photosensor function that uses TFDs or an electronic device with such a display device. Optionally, the present invention is also applicable to an image sensor including a photosensor that uses a TFD and a driver that uses a TFT.

### REFERENCE SIGNS LIST

100 semiconductor device
101, 201 substrate
102, 207 opaque layer
103, 104, 202, 203 undercoat film
105, 204 amorphous semiconductor film (for TFT)
105c, 205c crystalline semiconductor film
107, 206 thin-film transistor's semiconductor layer (crystalline semiconductor layer)
110, 210 thin-film diode's semiconductor layer (amorphous semiconductor layer)
108, 208 gate insulating film
109, 209 gate electrode
113, 213 source/drain regions
115, 215 channel region
114, 214 n-type region
118, 218 p-type region
119, 219 intrinsic region
121, 222 interlevel dielectric film
122, 123, 223, 224 electrodes and interconnects
124, 225 thin-film transistor
125, 226 thin-film diode

1. A semiconductor device comprising:
a substrate;
a thin-film transistor, which is supported by the substrate and which includes a crystalline semiconductor layer with a channel region and source and drain regions, a gate insulating film that is arranged to cover the crystalline semiconductor layer, and a gate electrode that is arranged on the gate insulating film to control the conductivity of the channel region; and
a thin-film diode, which is also supported by the substrate and which includes an amorphous semiconductor layer that has at least an n-type region and a p-type region,
wherein the amorphous semiconductor layer has been deposited on the gate insulating film in contact with the surface of the gate insulating film, and
wherein the n-type or p-type region and the source and drain regions have the same dopant element.

2. The semiconductor device of claim 1, wherein the thickness d2 of the amorphous semiconductor layer is greater than the thickness d1 of the crystalline semiconductor layer.

3. The semiconductor device of claim 1, wherein the thin-film transistor further includes an interlevel dielectric layer that contacts with the upper surface of the gate electrode, and
wherein the thin-film diode further includes an interlevel dielectric layer that contacts with the upper surface of the amorphous semiconductor layer, and
wherein the respective interlevel dielectric layers of the thin-film transistor and the thin-film diode are made of the same insulating film.

4. The semiconductor device of claim 1, wherein the depth Dd of a peak of the concentration profile of the same dopant element as measured in the thickness direction, and from the upper surface, of the n-type or p-type region is substantially equal to the depth Dt of another peak of the concentration profile of the same dopant element as measured in the thickness direction of the source and drain regions from the upper surface of the gate insulating film.

5. The semiconductor device of claim 1, wherein the thickness d2 of the amorphous semiconductor layer is greater than the sum (d1+d3) of the thickness d1 of the crystalline semiconductor layer and the thickness d3 of the gate insulating film.

6. The semiconductor device of claim 5, wherein the thickness d3 of the gate insulating film is measured on the source and drain regions of the crystalline semiconductor layer.

7. The semiconductor device of claim 1, wherein the amorphous semiconductor layer includes an intrinsic region between the n-type and p-type regions.

8. The semiconductor device of claim 1, wherein the amorphous semiconductor layer is a hydrogenated amorphous semiconductor layer in which dangling bonds of semiconductor atoms have been inactivated with hydrogen atoms.

9. The semiconductor device of claim 1, wherein the substrate is light-transmissive, and
wherein the device further includes an opaque layer between the amorphous semiconductor layer and the substrate.

10. The semiconductor device of claim 9, wherein the opaque layer and the crystalline semiconductor layer are made of the same semiconductor film.

11. A method for fabricating a semiconductor device, comprising the steps of:
(a) providing a substrate, of which the surface is already covered with a crystalline semiconductor film;
(b) patterning a portion of the crystalline semiconductor film into a first semiconductor island that will define the active region of a thin-film transistor;
(c) depositing a gate insulating film over the first semiconductor island;
(d) stacking an amorphous semiconductor film on the gate insulating film; and
(e) patterning a portion of the amorphous semiconductor film into a second semiconductor land that will define the active region of a thin-film diode.

12. The method of claim 11, wherein the amorphous semiconductor film is thicker than the crystalline semiconductor film.

13. The method of claim 12, wherein the thickness of the amorphous semiconductor film is greater than the combined thickness of the crystalline semiconductor film and the gate insulating film.

14. The method of claim 12, further comprising the step of forming a gate electrode for the thin-film transistor on the gate insulating film after the step (c) has been performed,
wherein the thickness of the amorphous semiconductor film is greater than the combined thickness of exposed portions of the crystalline semiconductor film and the gate insulating film that are not masked with the gate electrode.

15. The method of claim 11, further comprising the step of doping portions of the first semiconductor island to be source and drain regions and a portion of the second semiconductor island to be an n-type or p-type region with the same dopant element simultaneously after the step (e) has been performed.

16. The method of claim 11, further comprising, after the step (e), the steps of:
(f) doping portions of the first semiconductor island to be source and drain regions with a first dopant element through the gate insulating film;
(g) doping a portion of the second semiconductor island to be an n-type region with an n-type dopant element; and
(h) doping another portion of the second semiconductor island to be a p-type region with a p-type dopant element.

17. The method of claim 16, wherein the first dopant element includes an n-type dopant element, and
wherein the steps (f) and (g) are performed simultaneously.

18. The method of claim 16, wherein the first dopant element includes a p-type dopant element, and
wherein the steps (f) and (h) are performed simultaneously.

19. The method of claim 16, wherein the first semiconductor island comprises islands of semiconductor regions including islands to be the respective active regions of n-channel and p-channel thin-film transistors, and
wherein the step (f) includes the steps of (f1) doping one of the islands of semiconductor regions of the first semiconductor island, which will form part of the n-channel thin-film transistor, with the n-type dopant element through the gate insulating film, and (f2) doping another one of the islands of semiconductor regions of the first semiconductor island, which will form part of the p-channel thin-film transistor, with the p-type dopant element through the gate insulating film, and
wherein the steps (f1) and (g) are performed simultaneously, and
wherein the steps (f2) and (h) are performed simultaneously.

20. The method of claim 16, further comprising the step of forming a gate electrode for the thin-film transistor on the gate insulating film after the step (c) has been performed,
wherein the step (f) includes introducing the first dopant element using the gate electrode as a mask, and
wherein the method further comprises the step of irradiating that portion of the first semiconductor island, which has been doped with the first dopant element, with a laser beam through the gate insulating film, thereby activating the first dopant element in the first semiconductor island after the steps (f), (g) and (h) have been performed, and
wherein the thickness d3 (nm) of an exposed portion of the gate insulating film that is not masked with the gate electrode, the wavelength λ (nm) of the laser beam, and the refractive index n of the gate insulating film satisfy the inequality:
m×λ/(4×n)−15≦d3m×λ/(4×n)+15
where m is an integer that is equal to or greater than one.

21. The method of claim 11, wherein the substrate is light-transmissive, and
wherein the method further includes the step of forming an opaque layer for cutting light that has come from under the opposite surface of the substrate on a region of the substrate, which will be located under the second semiconductor island to be the active region of a thin-film diode, before the step (c) is performed.

22. The method of claim 21, wherein the step (b) includes patterning the crystalline semiconductor film into the first semiconductor island to be the active region of a thin-film transistor and at least a part of the opaque layer simultaneously.

23. The method of claim 11, wherein the step (a) includes the steps of:
(a1)) providing a substrate, of which the surface is already covered with another amorphous semiconductor film; and
(a2) irradiating and crystallizing that another amorphous semiconductor film with a laser beam, thereby forming a crystalline semiconductor film.

24. The method of claim 11, wherein the step (a) includes the steps of:
(a1)) providing a substrate, of which the surface is already covered with another amorphous semiconductor film;
(a2) adding a catalyst element, which promotes crystallization, to that another amorphous semiconductor film; and
(a3) heating and crystallizing that another amorphous semiconductor film to which the catalyst element has been added, thereby forming a crystalline semiconductor film.

25. A semiconductor device fabricated by the method of claim 11.

26. A display device comprising:
a display area including a plurality of display units; and
a frame area, which surrounds the display area,
wherein the device further includes a photosensor unit with a thin-film diode, and
wherein each said display unit includes an electrode and a thin-film transistor that is connected to the electrode, and
wherein the thin-film transistor and the thin-film diode have been formed on the same substrate, and
wherein the thin-film transistor includes a crystalline semiconductor layer with a channel region and source and drain regions, a gate insulating film that is arranged to cover the crystalline semiconductor layer, and a gate electrode that is arranged on the gate insulating film to control the conductivity of the channel region, and
wherein the thin-film diode includes an amorphous semiconductor layer that has at least an n-type region and a p-type region, and
wherein the amorphous semiconductor layer has been deposited on the gate insulating film in contact with the surface of the gate insulating film, and
wherein the n-type or p-type region and the source and drain regions have the same dopant element.

27. The display device of claim 26, wherein the display unit further includes a backlight and a backlight controller for controlling the luminance of the light emitted from the backlight, and
wherein the photosensor unit generates an illuminance signal representing the illuminance of external light and outputs the illuminance signal to the backlight controller.

28. The display device of claim 26, further comprising multiple optical touchscreen sensors, each of which includes the photosensor unit and is arranged in the display area for associated one, two or more of the display units.
